(19) United States
(12) Patent Application Publication
(10) Pub. No.: US 2026/0096218 A1
(43) Pub. Date: Apr. 2, 2026

(54) CELL REGION HAVING SOURCE REGION LOCATION-RESTRICTIONS AND DRAIN REGION LOCATION-RESTRICTIONS AND METHOD OF MANUFACTURING SAME

(71) Applicant: TAIWAN SEMICONDUCTOR MANUFACTURING COMPANY, LTD., Hsinchu (TW)

(72) Inventors: Yi-Yi CHEN, Hsinchu (TW); Chi-Yu LU, Hsinchu (TW); Shun Li CHEN, Hsinchu (TW); Chih-Liang CHEN, Hsinchu (TW); Ya-Chi CHOU, Hsinchu (TW); Chen-Ling WU, Hsinchu (TW); Li-Chun TIEN, Hsinchu (TW); Yung-Chin HOU, Hsinchu (TW)

(21) Appl. No.: 19/041,464

(22) Filed: Jan. 30, 2025

Related U.S. Application Data
(60) Provisional application No. 63/701,239, filed on Sep. 30, 2024.

(51) Int. Cl. H10D 89/10; H10D 84/85

(52) U.S. Cl. CPC H10D 89/10; H10D 84/85

(57) ABSTRACT

A cell region (of a device) includes: a first active region (AR); first MD structures aligning to beta tracks; and in a first metallization layer, segments aligning to alpha tracks. For one or more first or second locations, a corresponding region of the first AR is configurable as a source region or a drain region. For one or more third locations, a corresponding region of the first AR is configurable as a source region, but not as a drain region. For one or more fourth locations, a corresponding region of the AR is not configurable as a source region or a drain region. Each of the first to fourth locations is at an intersection of a corresponding alpha track and a corresponding beta track.

### PRIORITY CLAIM

The application claims the priority of U.S. Provisional Application No. 63/701,239, filed Sep. 30, 2024, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a block diagram, in accordance with some embodiments.

FIGS. 2A-2D are corresponding layout diagrams, in accordance with some embodiments.

FIGS. 3A-3C are corresponding layout diagrams, in accordance with some embodiments.

FIGS. 4A-4C are corresponding layout diagrams, in accordance with some embodiments.

FIG. 4D is a cross-section, in accordance with some embodiments.

FIGS. 5A-5G are corresponding layout diagrams, in accordance with some embodiments.

FIGS. 6 and 7 are flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a cell region (of a device) includes: a first active region (AR); first metal-to-source/drain contact (MD) structures aligning to beta tracks; and in a first metallization layer, segments aligning to alpha tracks. For one or more first or second locations, a corresponding region of the first AR is configurable as a source region or a drain region. For one or more third locations, a corresponding region of the first AR is configurable as a source region but not as a drain region. For one or more fourth locations, a corresponding region of the AR is is not configurable as a source region or a drain region. Each of the first to fourth locations is at an intersection of (A) a corresponding one of the alpha tracks and (B) a corresponding one of the beta tracks. The first to fourth locations are the subjects correspondingly of first to fourth design rules. In a Y-abutted arrangement of cell regions, the first to fourth design rules ensure that a distance gap_MD_ez separates adjacent MD structures which are aligned to the subject beta track. Distance gap_MD_ez is at least significantly, if not substantially, greater than a minimum distance gap_MD_min between adjacent co-beta-track-aligned MD structures which can be produced by a corresponding semiconductor process technology node.

Consider another approach for producing a cell region that is a counterpart to the cell region of at least some embodiments, where the counterpart cell region is used in a Y-abutted arrangement that is a counterpart to the Y-abutted arrangement of at least some embodiments. According to the other approach, there is no counterpart to the fourth design rule. The other approach's lack of a counterpart fourth design rule permits counterpart fourth locations to be configured as a source region or as a drain region resulting in the upper instance of co-beta-track-aligned counterpart MD structures being separated from the lower instance merely by a counterpart distance gap_MD_min rather than a greater distance, where the latter is more easily achieved/manufactured. By contrast, a benefit of a Y-abutted arrangement based on the cell region of at least some embodiments which separates co-beta-track-aligned MD structures by at least distance gap_MD_ez, i.e., a benefit of using the fourth design rule, is that distance gap_MD_ez is easier to achieve/manufacture as compared to having to achieve/manufacture the counterpart distance gap_MD_min according to the other approach. Consequently, a Y-abutted arrangement of at least some embodiments enjoys resultant benefits including lower manufacturing costs, reduced time required to manufacture, improved performance (e.g., reliability), or the like, as compared to the other approach.

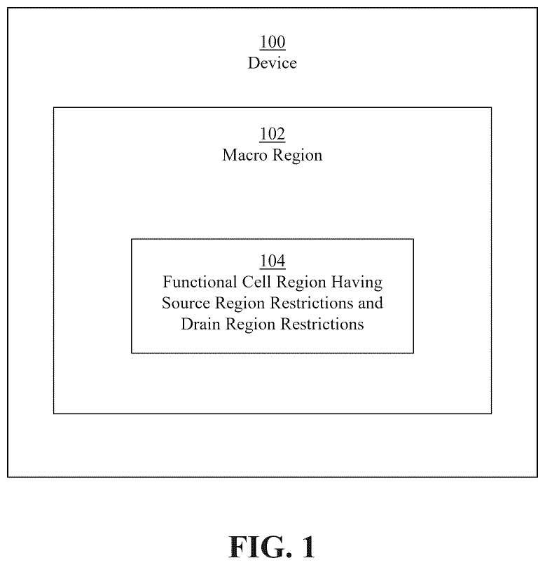

FIG. 1 is a block diagram of a device 100 that includes a functional cell region 104, in accordance with some embodiments.

Device 100 is an example of an integrated circuit (IC). In some embodiments, device 100 is referred to as a semiconductor device. Device 100 includes a macro region 102. Macro region 102 includes a cell region 104 which is functional. In some embodiments, functional cell region 104 includes one or more active devices, passive devices, or the like. Examples of active devices or active elements include, but are not limited to, transistors, diodes, or the like. Examples of passive elements include, but are not limited to, capacitors, inductors, fuses, resistors, or the like.

In some embodiments, macro region 102 is comprised of one or more instances of functional cell region 104 and/or one or more other functional cell regions. In such embodiments, macro region 102 is configured to provide/execute a given computational function which is comprised of less complicated functions provided correspondingly by the instances of functional cell region 104 and/or the one or more other functional cell regions. In some embodiments, one or more instances of functional cell region 104 and/or one or more other functional cell regions represent intercoupled building blocks which comprise macro region 102.

In some embodiments, macro region 102 is understood in the context of an analogy to the architectural hierarchy of modular programming, in which subroutines/procedures are called by a main program (or by other subroutines) to carry out a given computational function. In this context, device 100 uses macro region 102 to perform one or more given functions. Accordingly, in this context and in terms of architectural hierarchy, device 100 is analogous to the main program and macro region 102 is analogous to subroutines/procedures. In some embodiments, macro region 102 is a soft macro. In some embodiments, macro region 102 is a hard macro. In some embodiments, macro region 102 is a soft macro which is described digitally in register-transfer level (RTL) code. In some embodiments, synthesis, placement, and routing have yet to have been performed on macro region 102 such that the soft macro can be synthesized, placed, and routed for a variety of process technology nodes. In some embodiments, macro region 102 is a hard macro which is described digitally in a binary file format (e.g., Graphic Database System II (GDSII) stream format), where the binary file format represents planar geometric shapes, text labels, other information, and the like of one or more layouts of macro region 102 in hierarchical form. In some embodiments, a binary file format is referred to as a non-text file format. In some embodiments, synthesis, placement, and routing have been performed on macro region 102 such that the hard macro is specific to a particular process technology node.

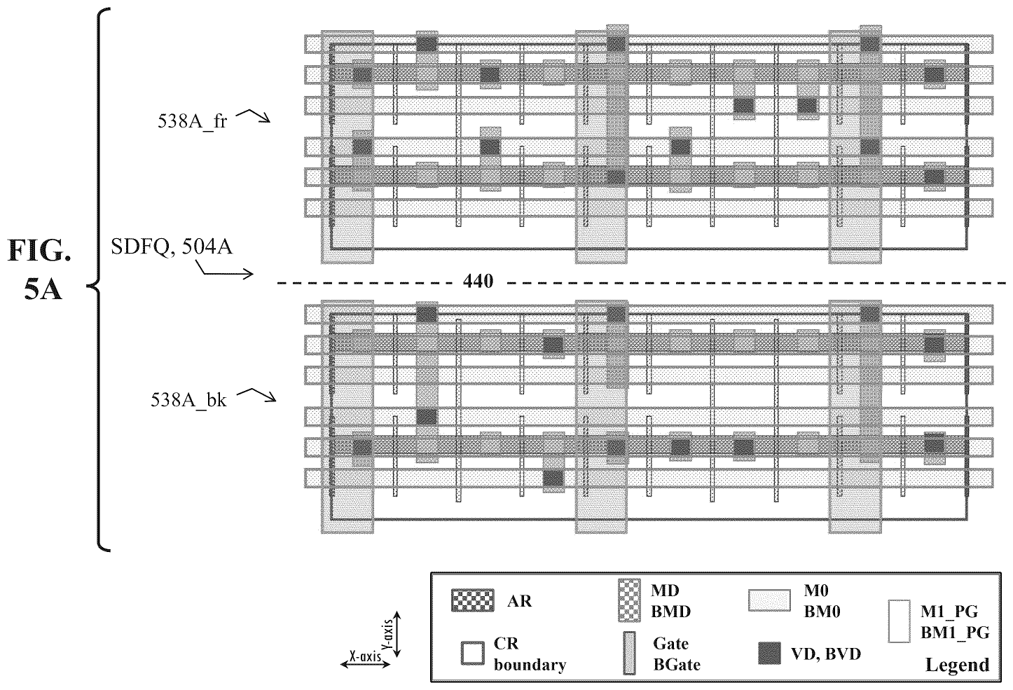

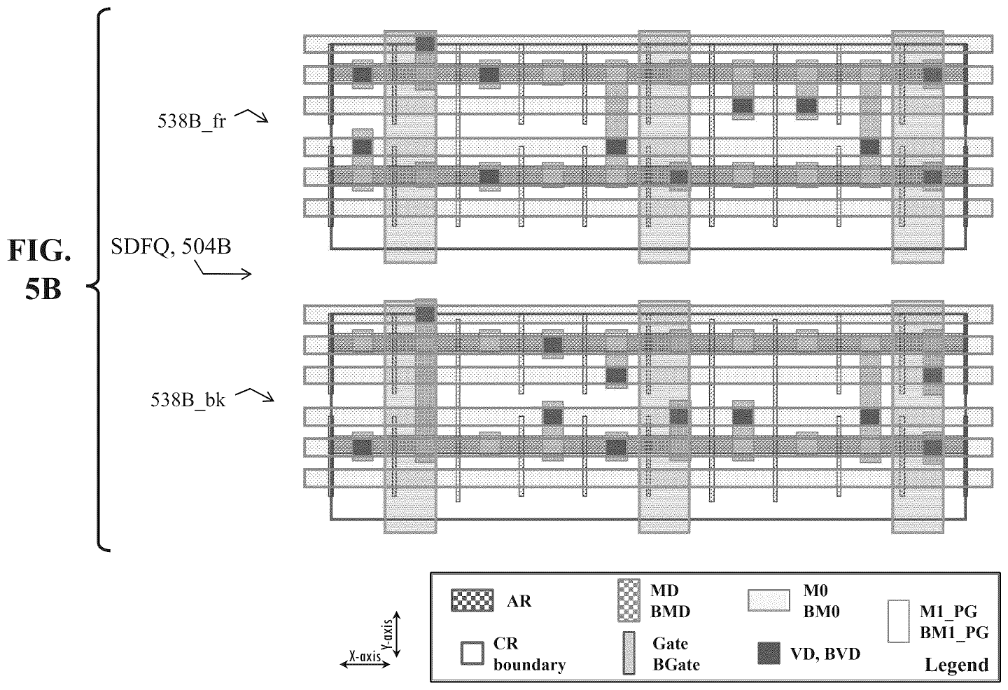

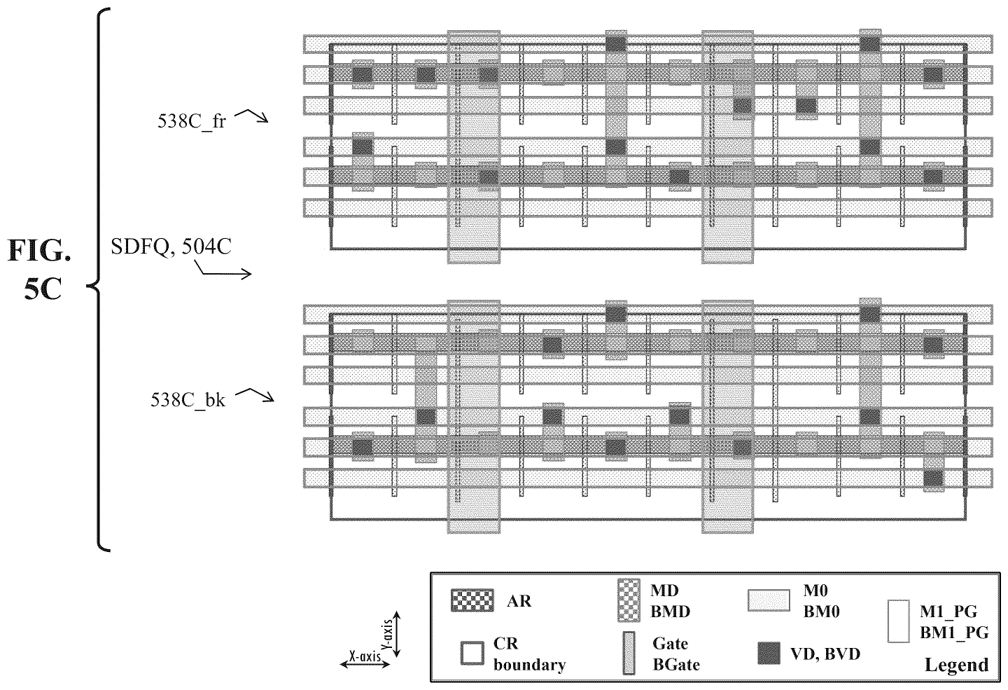

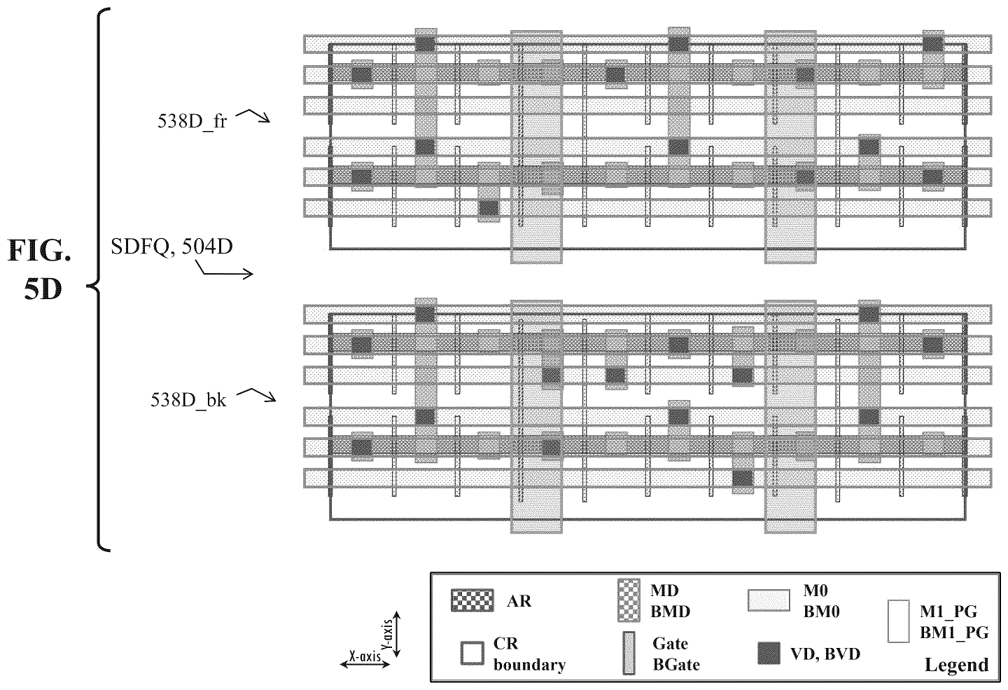

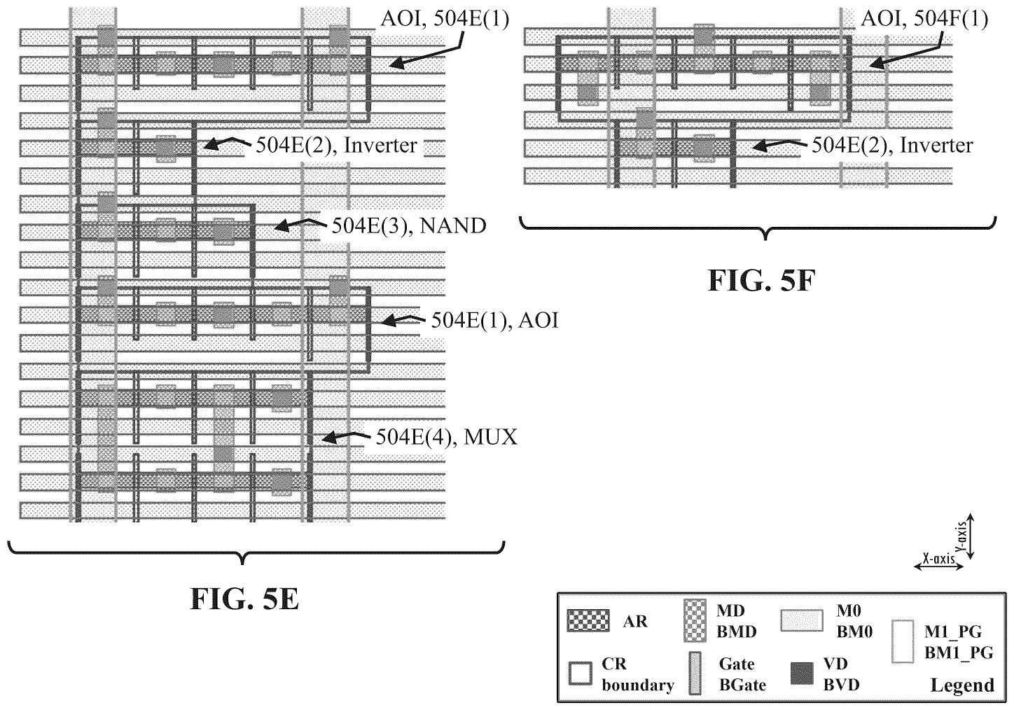

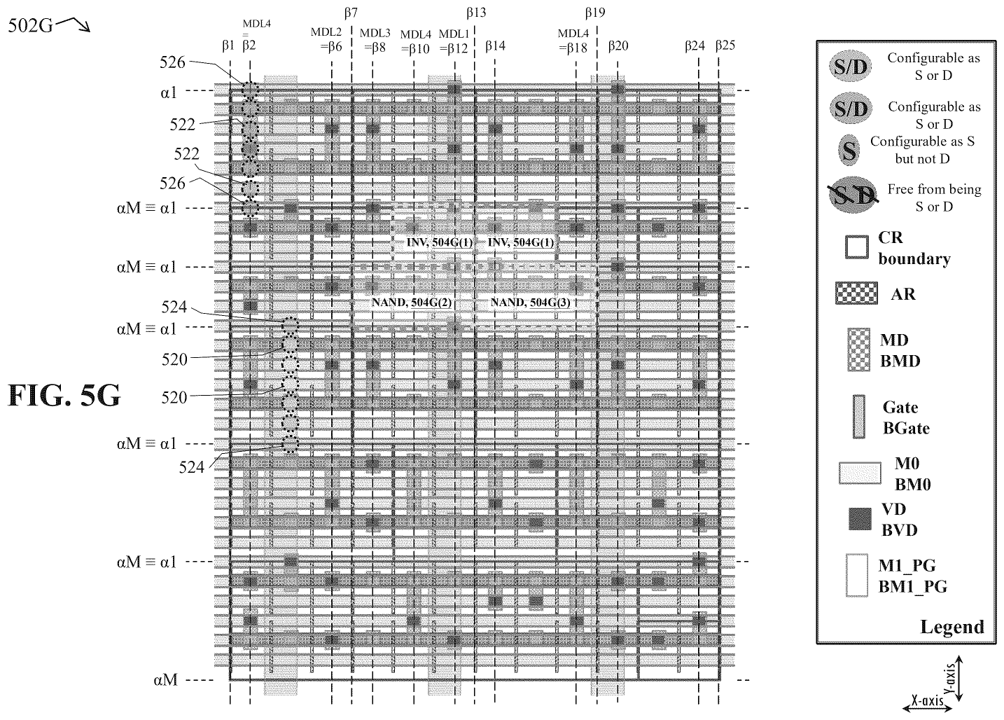

In some embodiments, examples of functions provided by a macro region (e.g., macro region 102) include a memory, a power grid, a clock tree, an adder, a phase-locked loop (PLL), a delay-locked loop (DLL), a flip-flop, a shift register, an analog-to-digital converter (ADC), a digital-to-analog converter (DAC), interfaces, higher-level Boolean logic, or the like. Example memories include a static random access memory (SRAM), a dynamic RAM (DRAM), a resistive RAM, a magnetoresistive RAM (MRAM), a read only memory (ROM), or the like. An example of a flip-flop is a scan-insertion type of D flip-flop (SDFQ), or the like. In some embodiments, examples of functions provided by functional cell regions (e.g., functional cell region 104) include an inverter, a buffer, a multiplexer (MUX), a driver, a latch, delay, lower-level Boolean logic, or the like, Examples of lower-level Boolean logic include AND, OR, NAND, NOR, XOR, INV, AND-OR-Invert (AOI) (see, e.g., FIG. 5A), OR-AND-Invert (OAI), or the like.,

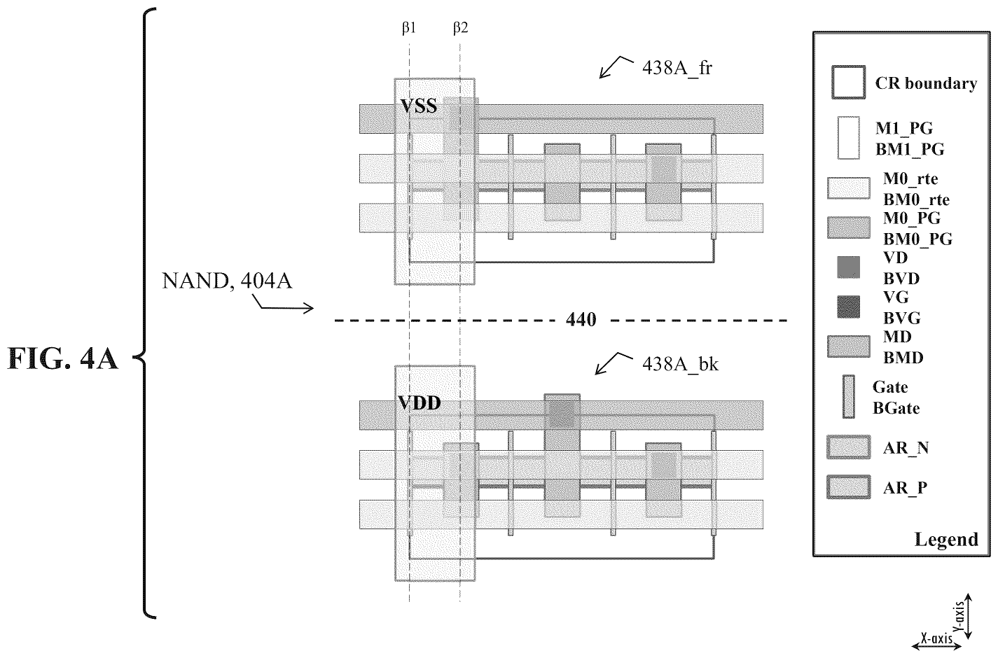

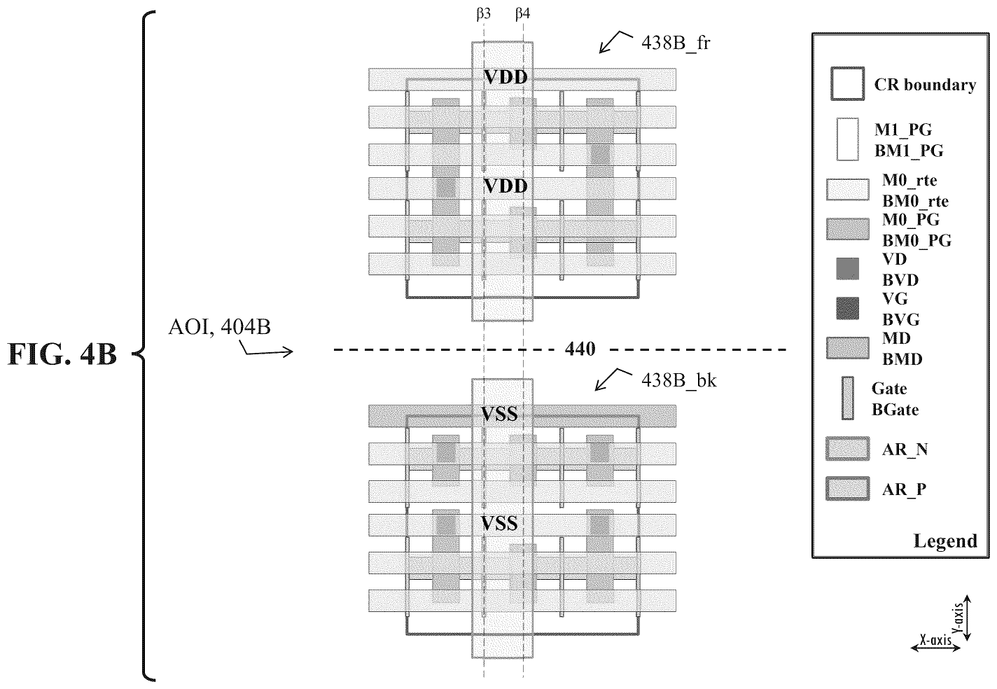

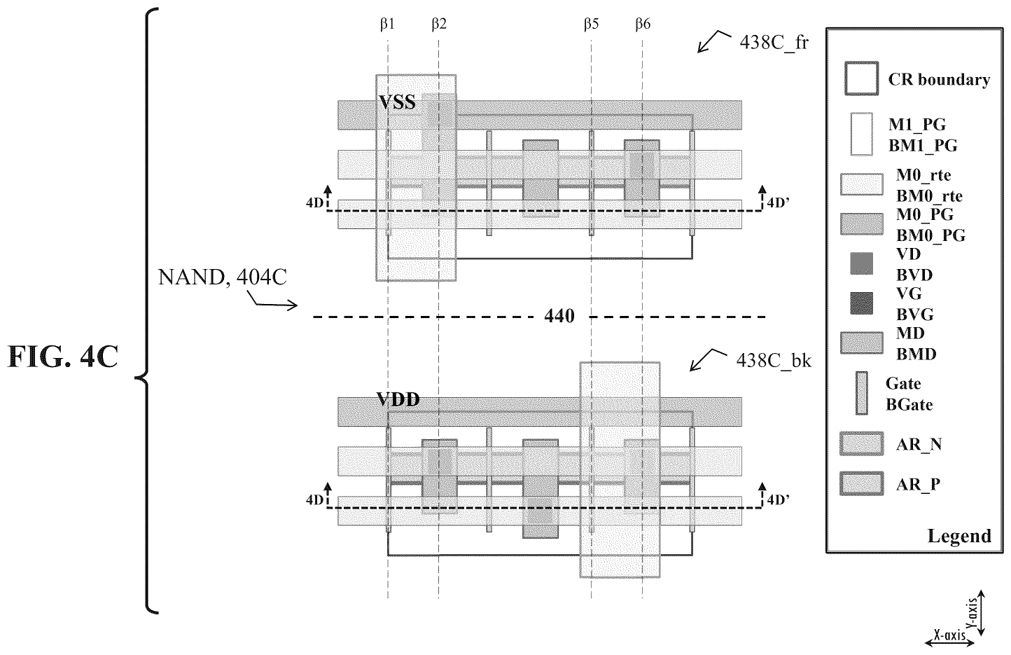

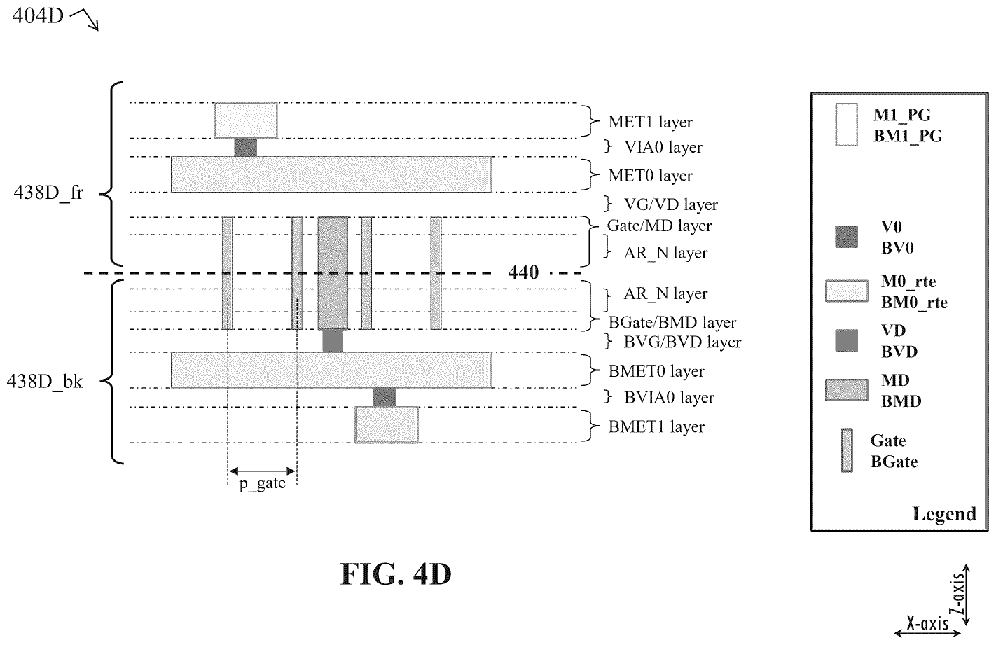

Functional cell region 104 includes corresponding segments in one or more metallization layers (see, e.g., FIG. 4G). Figures of the present disclosure assume a Cartesian coordinate system (unless noted otherwise) in which first, second and third directions are, e.g., correspondingly parallel to the X-axis, the Y-axis and the Z-axis. In some embodiments, the first to third directions correspond to directions other than the X-axis, Y-axis and Z-axis. In some embodiments, long and short axes of the segments extend correspondingly in the first and second directions in even ones of the metallization layers; in such embodiments, long and short axes of the segments extend correspondingly in the second and first directions in odd ones of the metallization layers. In such embodiments, boundaries of functional cell region 104 are described in terms of the first and second directions.

In some embodiments, functional cell region 104 corresponds to a transistor-components layer (see, e.g., FIG. 4D) having circuitry components, e.g., transistor, formed thereon in a front-end-of-line (FEOL) fabrication. In functional cell region 104, above and/or below an active region (AR) layer (see, e.g., FIG. 4D), various metal layers (see, e.g., FIG. 4D) are interleaved with corresponding interconnection layers (see, e.g., FIG. 4D) are stacked over and/or under insulating layers in a back end of line (BEOL) fabrication. The BEOL fabrication provides a power network and/or routing for circuitry of device 100, including macro region 102 and functional cell region 104.

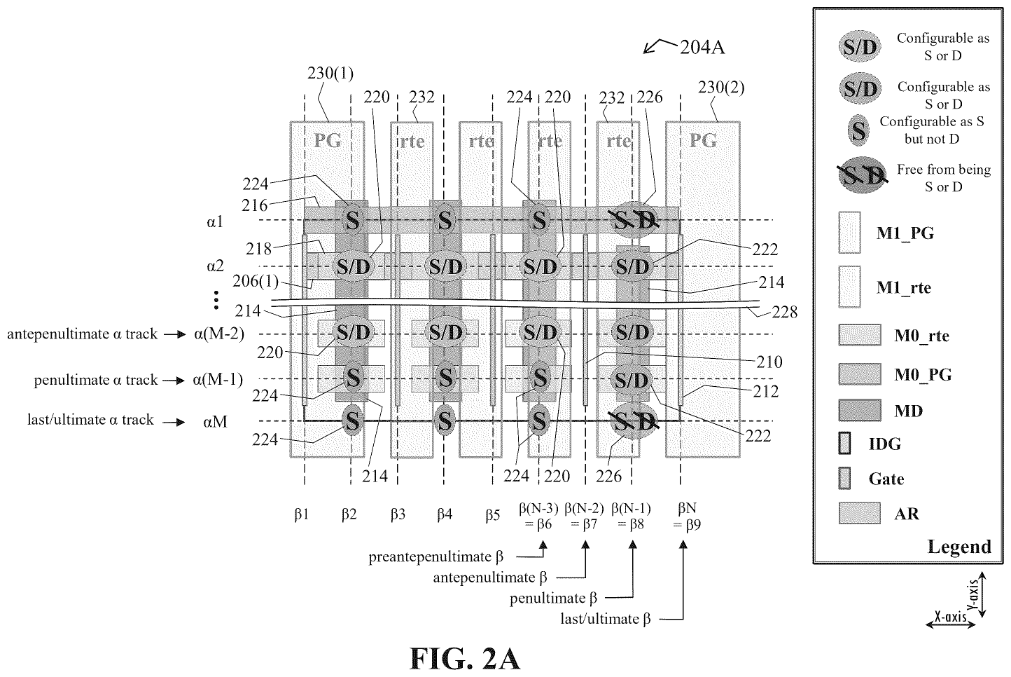

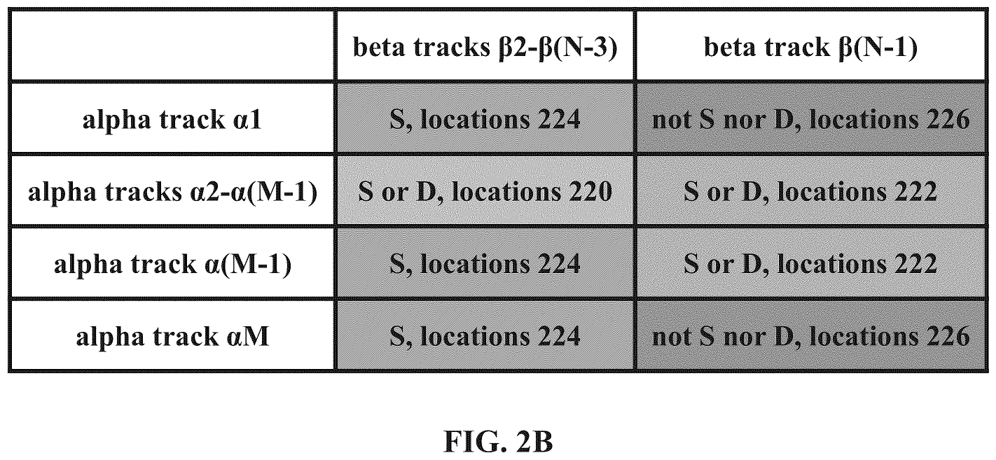

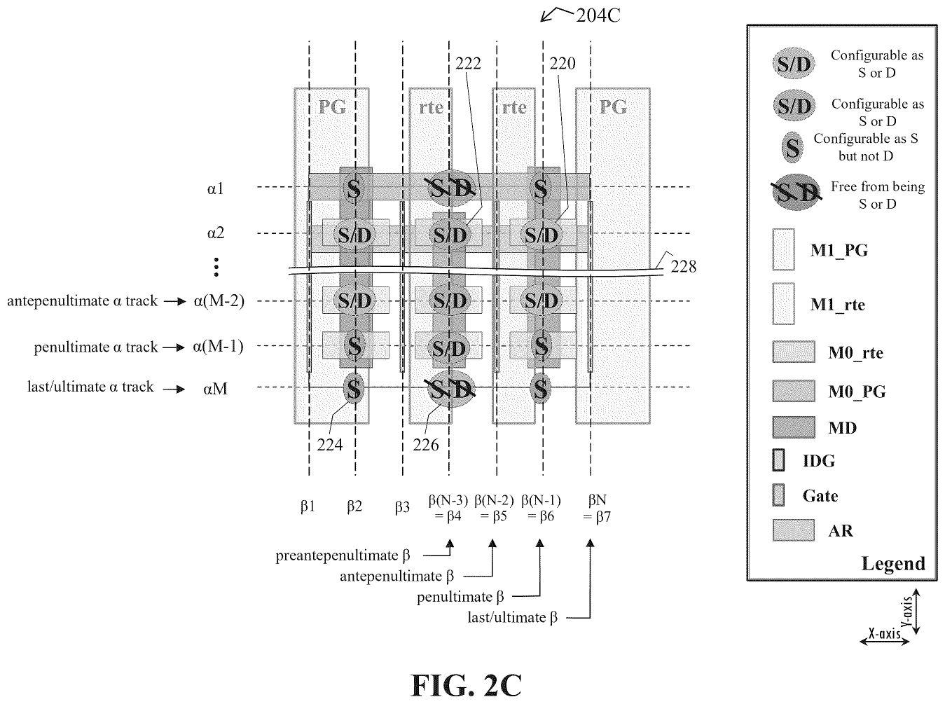

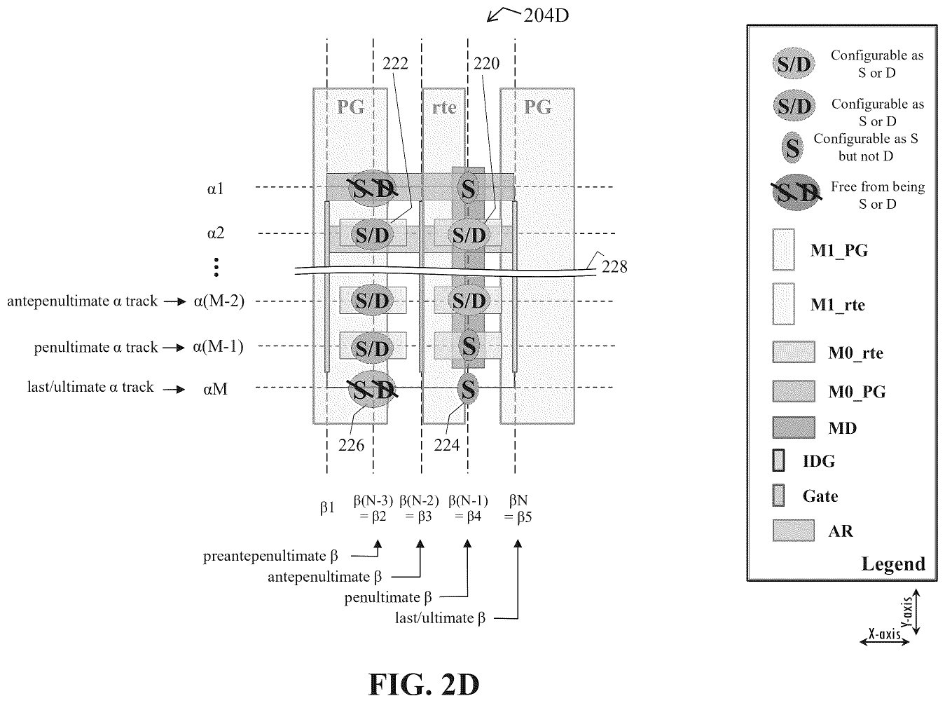

FIG. 2A is a layout diagram of a cell region 204A, in accordance with some embodiments.

Cell region 204A is an example of functional cell region 104 of FIG. 1. Cell region 204A is arranged relative to the following: alpha track (or alpha lines) α1-αM that extend parallel to the X-axis, where M is a positive integer and 3≤M; and beta tracks (beta lines) β1-βN that extend parallel to the Y-axis, where N is a positive integer and 3≤N.

In FIG. 2A, and in other layout diagrams disclosed herein, the first and second directions are assumed to be parallel correspondingly to the X-axis and the Y-axis. In some embodiments, the first and second directions are assumed to have orientations other than being parallel correspondingly to the X-axis and the Y-axis. In FIG. 2A, and in other layout diagrams disclosed herein, rows are collinear with the alpha tracks.

The layout diagram of FIG. 2A, and other layout diagrams disclosed herein, are representative of a transistor-based device. Structures in the device are represented by patterns (also known as shapes) in the layout diagram. For simplicity of discussion, elements in the layout diagrams of FIG. 2A (and also in other layout diagrams disclosed herein) will be referred to as if they are structures rather than patterns. For example, shapes in FIG. 2A representing instances of M0_rte segments are referred to as M0_rte segments per se rather than shapes.

A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. The layout diagrams disclosed herein are examples of layout diagrams in which selected layers and/or selected elements of depicted given layers, have been omitted.

In some embodiments, an isolation dummy gate (IDG) structure is a dielectric structure that includes one or more dielectric materials and functions as an electrical isolation structure. Accordingly, an IDG structure is not a structure that is electrically conductive and thus does not function, e.g., as an active gate of a transistor. An IDG structure includes one or more dielectric materials and functions as an electrical isolation structure. In some embodiments, an IDG structure is based on a gate segment as a precursor. In some embodiments, an IDG structure is based on a dummy gate structure. In some embodiments, a dummy gate structure includes a gate segment that is decoupled so as to not function, e.g., as a gate of a transistor, a gate-insulator layer, (optionally) one or more spacers, or the like. In some embodiments, an IDG structure is formed by first forming a gate segment e.g., which is included in a dummy gate structure, sacrificing/removing (e.g., etching) the gate segment to form a trench, (optionally) removing a portion of a substrate that previously had been under or over or around the gate segment to deepen the trench, and then filling the trench with one or more dielectric materials such that the physical dimensions of the resultant electrical isolation structure, i.e., the IDG, are similar to the dimensions of the gate segment which was sacrificed. In some embodiments, an IDG is a dielectric feature that includes one or more dielectric materials (e.g., oxide, nitride, oxynitride, or other suitable materials), and functions as an isolation feature. In some embodiments, an IDG is a continuous polysilicon on oxide diffusion (OD) edge structure, and is referred to as a CPODE structure.

According to one type of complementary metal-oxide-semiconductor (CMOS) architectures, negative-channel metal-oxide semiconductor (NMOS) transistors and positive-channel metal-oxide semiconductor (PMOS) transistors are distributed relative to the X-axis and the Y-axis, plus NMOS transistors are stacked over/under corresponding PMOS transistors relative to the Z-axis; in some embodiments, such an architecture is referred to as a stacked-CMOS architecture. Examples of the stacked-CMOS architecture is complimentary field-effect transistor (CFET) architecture, or the like. According to another type of CMOS architecture, NMOS transistors and PMOS transistors are distributed relative to the X-axis and the Y-axis, but NMOS transistors are not stacked over/under corresponding PMOS transistors relative to the Z-axis; in some embodiments, such an architecture is referred to as a non-stacked-CMOS architecture. Examples of the non-stacked-CMOS architecture include planar field-effect transistor (FET) architecture, finFET architecture, gate-all-around FET (GAAFET) architectures, or the like. Examples of the GAAFET architecture include as nanowire architecture, nanosheet architecture, forksheet architecture, or the like.

Depending upon the numbering convention of the corresponding process technology node by which a device is to be fabricated, on a front side (see, e.g., FIG. 4D) of the CFET architecture (see, e.g., FIG. 4D), the first layer metallization is either metallization layer zero (MET0) or metallization layer one (MET1), and correspondingly a first interconnection layer on the first metallization layer is either interconnection layer zero (VIA0) or interconnection layer one (VIA1). In such embodiments, again depending upon the numbering convention of the corresponding process technology node, on a back side (see, e.g., FIG. 4D) of the CFET architecture (see, e.g., FIG. 4D), the first buried metallization layer is either buried metallization layer zero (BMET0) or buried metallization layer one (BMET1), and correspondingly a first buried interconnection layer under the first metallization layer is either interconnection layer zero (VIA0) or interconnection layer one (VIA1).

In general regarding the figures disclosed herein (unless noted otherwise), the following nomenclature is adopted regarding the front side of CFET architecture: the first metallization layer is assumed to be MET0; the first interconnection layer is assumed to be VIA0; the second metallization layer is assumed to be MET1; the second interconnection layer is assumed to be VIA1; and the third metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

In general, regarding the figures disclosed herein (unless noted otherwise), or the like, the following nomenclature is adopted regarding the back side of CFET architecture: the first buried metallization layer is assumed to be BMET0; the first buried interconnection layer is assumed to be BVIA0; the second buried metallization layer is assumed to be BMET1; the second buried interconnection layer is assumed to be BVIA1; and the third buried metallization layer is assumed to BMET2. Metallization segments in layer BMET0 are referred to as buried M0 (BM0) segments. Via structures in layer BVIA0 are referred to as BV0 structures. Metallization segments in layer BMET1 are referred to as buried M1 (BM1) segments. Via structures in layer BVIA1 are referred to as BV1 structures. Metallization segments in layer BMET2 are referred to as buried M2 (BM2) segments.

Components included in cell region 204A include: an active region (AR) 206(1); gate segments 210 (see, e.g., FIG. 4D); metal-to-source/drain-region (MD) structures (see, e.g., FIGS. 2C-2E); isolation dummy gate structures 212; M0 segments (see, e.g., FIG. 4D) that extend substantially parallel to the X-axis; and M1 segments (see, e.g., FIG. 4D) that extend substantially parallel to the Y-axis.

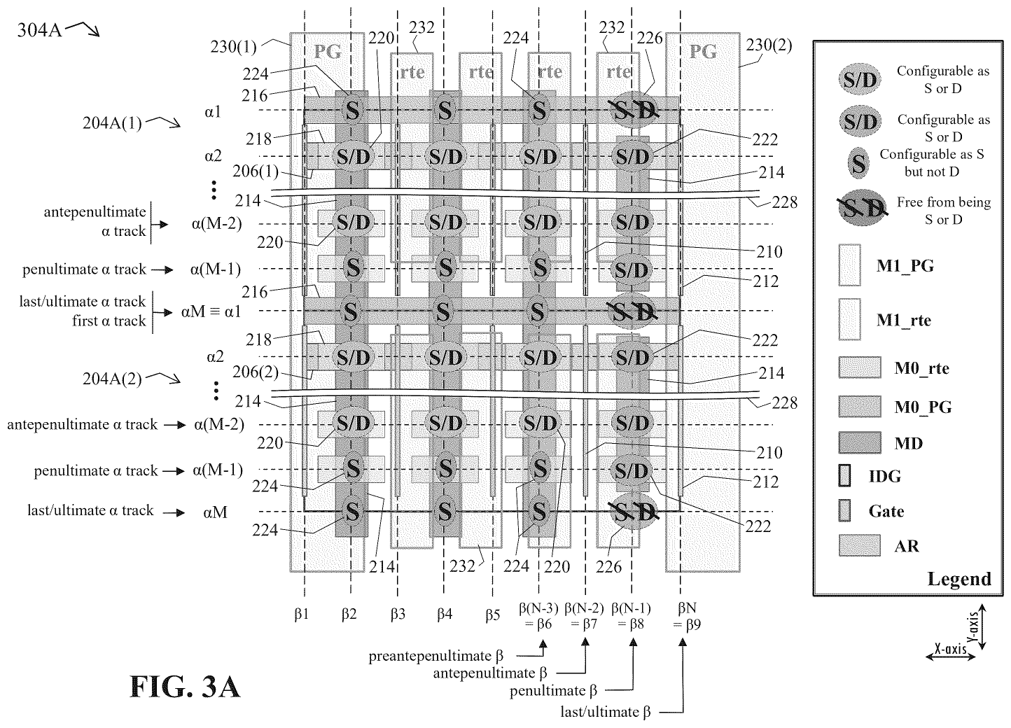

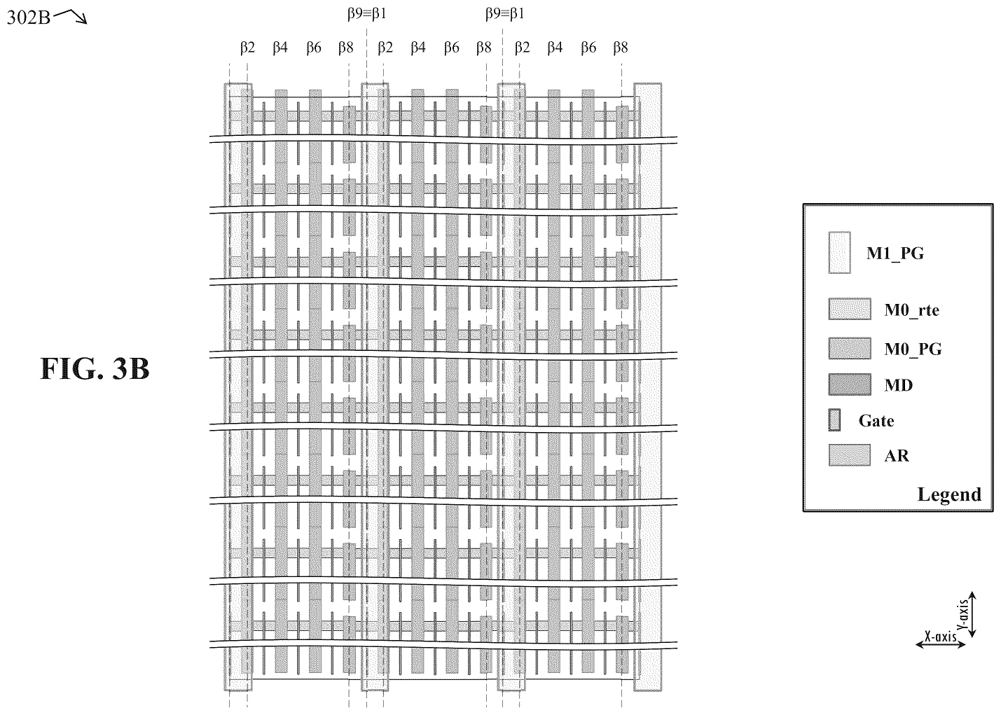

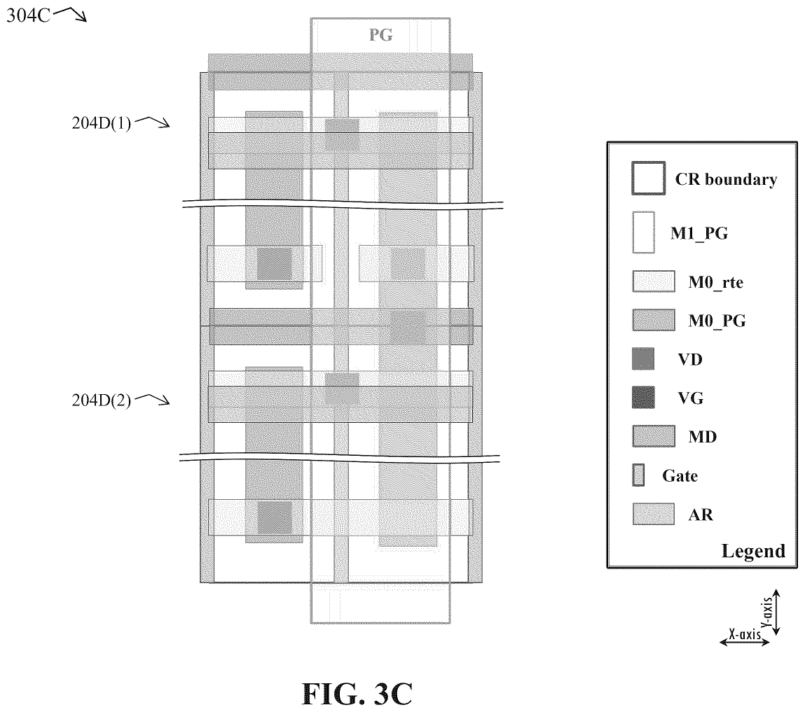

The M0 segments include a power grid (PG) segment (M0_PG segment) 216 and routing (RTE) segments (M0_rte segments) 218. The M1 segments include PG segments (M1_PG segments) 230(1)-230(2) and routing segments (M1_rte segments) 232. In some embodiments, one or more of the isolation dummy gate structures 212 are replaced by gate segments (see, e.g., FIG. 3B).

Regarding FIG. 2A, in some embodiments, cell region 20A represents one side of a stacked-CMOS architecture (see, e.g., FIGS. 4E-4G). In some embodiments, cell region 20A represents one side of a CFET architecture (see, e.g., FIGS. 4E-4G).

In FIG. 2A, first and last ones of the alpha tracks, i.e., alpha tracks α1 and αM, substantially align correspondingly to top and bottom boundaries of cell region 204A. First and last ones of the beta tracks, i.e., beta tracks β1 and βN, substantially align correspondingly to left and right boundaries of cell region 204A.

For simplicity of illustration in FIG. 2A, relative to the Y-axis, the middle portion of cell region 204A is omitted for simplicity of illustration, as indicated by break lines 228. Also for simplicity of illustration, relative to the X-axis, a width of cell region 204A is assumed to span nine beta tracks, i.e., to extend from beta track β1 and to beta track βN=β9. In some embodiments, the value of N is a positive integer that is 3≤N other than N=9.

In FIG. 2A, and in the other figures disclosed herein: the M0 segments are aligned to corresponding ones of the alpha tracks; and the gate segments, the MD structures and the IDGs are aligned to corresponding odd ones of the beta tracks. In cell region 204A, gate segments 210 are aligned to odd beta tracks β3, β5 and β7, and IDGs 212 are aligned to odd beta tracks β1 and β9. In general, the MD structures are aligned to even ones of the beta tracks. In cell region 204A, MD structures 214, e.g., beta tracks β2, β4, β6 and β8 in cell region 204A.

In FIG. 2A, relative to the X-axis, adjacent gate segments 210 are separated from each other by a uniform distance/pitch, p_gate. A value for pitch p_gate depends on the corresponding semiconductor process technology node. In some embodiments, pitch p_gate represents one contacted poly pitch (CPP) for the corresponding semiconductor process technology node. Here, the word ‘poly’ in the term CPP does not necessarily imply that the gate structures in semiconductor devices based correspondingly on FIG. 2D, or the like, are to be formed of polysilicon but instead represents a historical convenience, i.e., because gate structures in ICs manufactured according to a predecessor semiconductor process technology node often were formed of polysilicon. Adjacent beta tracks, e.g., beta tracks β2 and β4, are separated from each other by a uniform distance p_β, where distance p_β is equal to one-half of p_gate such that p_β=(p_gate/2).

In the example of FIG. 2A, relative to the X-axis, a width of cell region 204A, w_204A, is equal to 4*p_gate such that w_204A=(4*p_gate). In some embodiments, a width of a cell region, w_CR, is different than w_204A (see, e.g., FIGS. 2C-2D).

In general, where an MD structure overlaps an active region, the overlapped portion of the active region is configurable as a source region or as a drain region, i.e., the overlapped portion of the active region can be doped to serve as source region of a transistor or as a drain region of a transistor. In some embodiments, in the context of NMOS transistor technologies having an N-type active region, a source region and a drain region are doped with one or more N-type dopants relatively more heavily than other regions of the active region, with the source and drain regions being doped in substantially the same manner. In some embodiments, in the NMOS context, a source region and a drain region are doped with a substantially different sets of one or more N-type dopants, each of the source and drain region nevertheless being relatively more heavily doped than other regions of the active region. In some embodiments, in the NMOS context, a source region and a drain region are doped with the same sets of one or more N-type dopants albeit under different sets of doping process parameters, each of the source and drain region nevertheless being relatively more heavily doped than other regions of the active region. In some embodiments, in the context of PMOS transistor technologies having a P-type active region, a source region and a drain region are doped with one or more P-type dopants relatively more heavily than other regions of the active region, with the source and drain regions being doped in substantially the same manner. In some embodiments, in the PMOS context, a source region and a drain region are doped with a substantially different sets of one or more P-type dopants, each of the source and drain region nevertheless being relatively more heavily doped than other regions of the active region. In some embodiments, in the PMOS context, a source region and a drain region are doped with the same sets of one or more P-type dopants albeit under different sets of doping process parameters, each of the source and drain region nevertheless being relatively more heavily doped than other regions of the active region.

In the example of FIG. 2A, AR 206(1) is substantially aligned to alpha track α2. In some embodiments, AR 206(1) instead is substantially aligned to another alpha track, i.e., to one of alpha tracks α1 and α3-αM; it is noted that alpha track α3 is not shown in FIG. 2A, for simplicity of illustration. In some embodiments (not shown), cell region 204A includes two or more instances of AR 206(1) that are aligned substantially and correspondingly to two or more of alpha tracks α1-αM.

In FIG. 2A, MD structures 214 overlap AR 206(1) at intersections of beta tracks β2, β4, β6 and β8 and alpha track α2. Taking into consideration the different possible alpha-track-alignments of AR 206(1) and the possibility of cell region 206A including two or more instances of AR 206(1), the possible locations of overlap with one of MD structures 214 are at the intersections of beta tracks β2, β4, β6 and β8 and alpha tracks α1-αM.

To identify intersections of alpha tracks and beta tracks, cell region 206A of FIG. 2A and other cell regions disclosed herein assumed the following nomenclature. Alpha track α1 is referred to as the first alpha track. Alpha track α2 is referred to as the second alpha track . . . Alpha track αM is referred to as the last or ultimate alpha track. Alpha track α(M−1) is referred to as the penultimate alpha track. Alpha track α(M−2) is referred to as the antepenultimate alpha track. Alpha track α(M−3) is referred to as the preantepenultimate alpha track. Beta track β1 is referred to as the first beta track. Beta track β2 is referred to as the second beta track . . . Beta track βN is referred to as the last or ultimate beta track, where N=9 in the example of FIG. 2A such that βN=β9. Beta track β(N−1) is referred to as the penultimate beta track, where N−1=8 in the example of FIG. 2A such that β(N−1)=β8. Beta track β(N−2) is referred to as the antepenultimate beta track, where N−2=7 in the example of FIG. 2A such that β(N−2)=β7. Beta track β(N−3) is referred to as the preantepenultimate beta track, where N−3=6 in the example of FIG. 2A such that β(N−3)=β6.

FIG. 2A assumes a first to fourth design rules for cell region 206A which take into consideration the different possible alpha-track-alignments of AR 206(1) and the possibility of cell region 206A including two or more instances of AR 206(1). The first to fourth design rules assume the following: (i) the gate segments and the MD structures are interleaved relative to the X-axis; (ii) the gate segments are aligned to odd-numbered ones of the beta tracks (gate-aligned beta tracks) and the MD structures are aligned to even-numbered ones of the beta tracks (MD-aligned beta tracks); (iii) a macro region (e.g., 302B of FIG. 3B) includes instances of cell regions (e.g., 204A) that have the same width relative to the X-axis; and (iv) the macro region is an example of an X-abutted arrangement (discussed below). Though the discussion of the first to fourth rules in the context of FIG. 2A includes generalizations beyond the example of FIG. 2A, nevertheless the generalizations assume that a macro region (e.g., 302B of FIG. 3B) includes instances of cell regions (e.g., 204A) that have the same width relative to the X-axis and that such a macro region is an example of an X-abutted arrangement (discussed below). Below, in the context of FIG. 5G, further generalizations of the first to fourth design rules will be discussed regarding how the first to fourth design rules are expressed for use in the context of a macro region (e.g., 502G) that includes cell regions of various widths.

The first design rule is directed to (or is concerned with) first locations 220 of possible overlap between one of MD structures 214 and an active region (e.g., 206(1)). First locations 220 are at intersections of (A) alpha tracks α2-α(M−2) and (B) alternating ones of beta tracks β2-β6, i.e., at beta tracks β2, β4 and β6. More generally, first locations 220 are at intersections of (A) the second through antepenultimate alpha tracks and (B) alternating ones of the second through preantepenultimate beta tracks. At each of first locations 220, the first design rule dictates that the overlapped region of the active region (e.g., 206(1)) is configurable as a source region or a drain region.

The second design rule is directed to (or is concerned with) second locations 222 of possible overlap between one of MD structures 214 and an active region (e.g., 206(1)). Second locations 222 are at intersections of alpha tracks α2-α(M−1) and (B) beta track β8. More generally, second locations 222 are at intersections of (A) the second through penultimate alpha tracks and (B) the penultimate beta track. At each of second locations 222, the second design rule dictates that the overlapped region of the active region (e.g., 206(1)) is configurable as a source region or a drain region.

The third design rule is directed to (or is concerned with) third locations 224 of possible overlap between one of MD structures 214 and an active region (e.g., 206(1) ). Third locations 224 are at intersections of alpha tracks α1 and αM and (B) alternating ones of beta tracks β2-β6, i.e., at beta tracks β2, β4 and β6. More generally, third locations 224 are at intersections of (A) the first and last alpha tracks and (B) alternating ones of the second through preantepenultimate beta tracks. At each of third locations 224, the third design rule dictates that the overlapped region of the active region (e.g., 206(1)) is (i) configurable as a source region and (ii) free of being configurable as a drain region, i.e., is not to be configured as a drain region.

The fourth design rule is directed to (or is concerned with) fourth locations 226 of possible overlap between one of MD structures 214 and an active region (e.g., 206(1)). In FIG. 2A, beta track β8 is assumed to be the beta track which is the subject of the fourth design rule. Fourth locations 226 are at intersections of alpha tracks α1 and αM and (B) beta track β8. More generally, fourth locations 226 are at intersections of (A) the first and last alpha tracks and (B) the penultimate beta track. At each of fourth locations 226, the fourth design rule dictates that the overlapped region of the active region (e.g., 206(1)) is free of being configurable as a source region or a drain region, i.e., is not to be configured as a source region nor as a drain region.

In some embodiments, one of beta tracks β2, β4 or β6 is the subject of the fourth design rule rather than beta track β8. In some embodiments in which the subject of the fourth design rule is one of beta tracks β2, β4 or β6, at least the following would true: the fourth locations 226 would be repositioned, i.e., the alpha/beta track intersections of the fourth locations 226 would be changed, so that the fourth locations would be aligned to the other one of beta track β2, β4 or β6; and a corresponding number (e.g., two) of instances of location 224 would be repositioned so that the repositioned instances of location 224 would be aligned to beta track β8. In some embodiments, additional instances of location 224 and/or one or more instances of location 220 and/or location 222 would be repositioned correspondingly.

In some embodiments, the subject of the fourth design rule is the penultimate beta track, e.g., beta track β8 as in FIG. 2A. In some embodiments, the subject of the fourth design rule is the preantepenultimate beta track, e.g., beta track β4 as in FIG. 2C or beta track β2 as in FIG. 2D.

In FIG. 2A, beta tracks β2, β4 and β6 are assumed to be the beta tracks which are the subjects of the sixth design rule. In some embodiments, a set of the beta tracks (e.g., a set of three) other than the set of beta tracks β2, β4 and β6 is the subject of the sixth design.

In FIG. 2A, M0_PG segment 216 is substantially aligned to alpha tracks α1. More generally, M0_PG segment 216 is substantially aligned to the first alpha track. In some embodiments, M0_PG segment 216 is collinear with alpha track α1. In FIG. 2A, M0_rte segments 218 are substantially aligned to corresponding ones of alpha tracks α2-α(M−1). More generally, M0_rte segments 218 are substantially aligned to corresponding ones of the second through penultimate alpha tracks. In some embodiments, M0_rte segments 218 are collinear with corresponding ones of alpha tracks α2-α(M−1).

Cell region 204A is free of having an instance of M0_PG segment 216 or M0_rte segment 218 aligned to alpha track αM. In some embodiments (see, e.g., FIG. 3A), a first instance of cell region 204A is abutted to a second instance of cell region 204 relative to the Y-axis (Y-abutted arrangement) such that the last alpha track (e.g., αM) of the first instance of cell region 204A is substantially collinear with the first alpha track (e.g., α1) of the second instance of cell region 204A resulting in M0_PG segment 216 of the first instance of cell region 204A being shared by the second instance of cell region 204A.

In some embodiments, the fourth design rule is described as dictating that each of fourth locations 226 is free of being overlapped by a portion of one of the MD structures 214. Because fourth locations 226 are not overlapped by a portion of one of the MD structures 214, it is beneficial to avoid configuring the regions of the active region (e.g., 206(1)) at the fourth locations as a source region or as a drain region; for example, it is beneficial because being free of being configured as a source region or as a drain region makes the regions of the active region (e.g., 206(1)) at the fourth locations less susceptible to noise propagation, or the like. In some embodiments, the fourth design rule is described as imposing MD-structure-location restrictions.

In some embodiments directed to a Y-abutted arrangement (e.g., see FIG. 3A) in which a first instance of a cell region (e.g., 204A) is over and abutted to a second instance of cell region (e.g., 204A), the following would be true: alpha track αM of the upper instance of cell region 204A corresponds to alpha track α1 of the lower instance of cell region 204A; and one or more instances of MD structure 214 extend continuously from the upper instance of cell region 204A into the lower instance of cell region 204A. That is, in the example, one or more instances of MD structure 214 extend continuously across alpha track αM of the upper instance of cell region 204A, i.e., extend continuously across alpha track α1 of the lower instance of cell region 204A, and further extend continuously across at least alpha track α2 of the lower instance of cell region 204A.

In the example of FIG. 2A, each of M0_rte segments 218 is shown as having a length (relative to the X-axis) sufficient to overlap a single location at which one of MD structures 214 overlaps (i) AR 206(1) or (ii) another AR (not shown), for simplicity of illustration.

Hence, in the example of FIG. 2A, each instance of M0_rte segment 218 overlaps (i) a corresponding single instance of first location 220, (ii) a single instance of second location 222, or a single instance of third location 224 that is aligned to alpha track α(M−1). In some embodiments, one or more instances of M0_rte 218 are longer, i.e., have a length sufficient to overlap two or more locations at which one of MD structures 214 overlaps (i) AR 206(1) or (ii) another AR (not shown).

Relative to the X-axis, M0_PG segment 216 is a rail that extends continuously (i) between the left and right boundaries of cell region 204A and (ii) beyond each of the left and right boundaries of cell region 204A. In some embodiments, e.g., in a stacked-CMOS architecture, each of M1_PG segments 230(1)-230(2) is configured for a first reference voltage, e.g., VDD, or a different second reference voltage, e.g., VSS. In some embodiments, e.g., in a non-stacked-CMOS architecture having a Y-abutted arrangement (e.g., see FIG. 3A) in which M0_PG segment 216 in a first instance of cell region 204A is shared by a second instance of cell region 204A, M1_PG segment 230(1) in the first instance of cell region 204A is configured for the first reference voltage (e.g., VDD or VSS) and M0_PG segment 216 in the second instance of cell region 204A is configured for the second reference voltage (e.g., correspondingly, VSS or VDD).

Relative to the Y-axis, M1_PG segments 230(1)-230(2) are rails that extends continuously (i) between the top and bottom boundaries of cell region 204A and (ii) beyond each of the top and bottom boundaries of cell region 204A. In some embodiments, e.g., in a stacked-CMOS architecture, each of M1_PG segments 230(1)-230(2) is configured for the same reference voltage, e.g., VDD or VSS. In some embodiments, e.g., in a non-stacked-CMOS architecture, M1_PG segment 230(1) is configured for the first reference voltage (e.g., VDD or VSS) and M1_PG segment 230(2) is configured for the second reference voltage (e.g., correspondingly, VSS or VDD).

In FIG. 2A, relative to the Y-axis, each of M0_PG segment 216 and M0_rte segments 218 have substantially the same width w_M0_common. Relative to the X-axis, each of M1_PG segments 230(1)-230(2) has a width w_M1_PG and each of M1_rte segments 232 has a width w_M1_rte. Width w_M1_PG is greater than width w_M1_rte such that w_M1_rte<w_M1_PG. Also, width w_M0_common is less than width w_M1_PG such that w_M0_common<w_M1_PG. In some embodiments, width w_M0_common is less than width w_M1_rte such that w_M0_common<w_M1_rte.

In some embodiments, as compared to a cell region in which a counterpart M0_PG segment has a width w_M0_PG greater than width w_M0_common, and an overall height h_cntrprt. Relative to the Y-axis, a height of cell region 204A, h_204A, is smaller than height h_cntrprt of the counterpart cell region. In some embodiments, (≈0.7*h_cntrprt)≤h_204A≤(≈0.95*h_cntrprt).

In some embodiments directed to a Y-abutted arrangement (e.g., see FIG. 3A) in which a first instance of cell region 204A is abutted to a second instance of cell region 204A, and regarding the beta track which is the subject of the fourth design rule, a distance gap_MD_ez separates adjacent MD structures which are aligned to the subject beta track. For example, assuming that cell region 204A of FIG. 2A is used in a Y-abutted arrangement in which the first instance of cell region 204A is over and abutted to the second instance of cell region 204A, the following would be true: each of the instance of MD structure 214 in the first instance of cell region 204A (upper instance of MD structure 214) and the instance of MD structure 214 in the second instance of cell region 204A (lower instance of MD structure 214) would be aligned to beta track β8; the upper instance of MD structure 214 and the lower instance of MD structure 214 are assumed to be adjacent; and the lower end of the upper instance of MD structure 214 would be separated from the upper end of the lower instance of MD structure 214 by distance gap_MD_ez.

In some embodiments, distance gap_MD_ez is at least significantly, if not substantially, greater than a minimum distance gap_MD_min between adjacent co-beta-track-aligned MD structures (e.g., 214) which can be produced by a corresponding semiconductor process technology node. For example, consider a given semiconductor process technology node that uses fewer masks (e.g., one mask) to achieve/manufacture distance gap_MD_ez that the number (e.g., two or greater) used to achieve/manufacture distance gap_MD_min. In some circumstances, the masks used by the given semiconductor process technology node are EUVL masks, where EUVL is an acronym for Extreme Ultraviolet Lithography. Because distance gap_MD_ez is greater than distance gap_MD_min such that gap_MD_min<gap_MD_ez, distance gap_MD_ez is easier to achieve/manufacture than distance gap_MD_min resulting in lower manufacturing costs, reduced time required to manufacture, improved performance (e.g., reliability), or the like.

Consider another approach for producing a cell region that is a counterpart to cell region 204A, where the counterpart cell region is used in a Y-abutted arrangement that is a counterpart to a Y-abutted arrangement (e.g., see FIG. 3A) based on cell region 204A. Relative to the Y-axis, an overall height of the counterpart Y-abutted arrangement is assumed to be substantially the same as the overall height of the Y-abutted arrangement based on cell region 204A. According to the other approach, there is no counterpart to the fourth design rule. The other approach's lack of a counterpart fourth design rule permits counterpart fourth locations to be configured as a source region or as a drain region resulting in the upper instance of the counterpart MD structure being separated from the lower instance of the counterpart MD structure merely by a counterpart distance gap_MD_min rather than a greater distance, where the latter is more easily achieved/manufactured. By contrast, a benefit of a Y-abutted arrangement based on cell region 204A which separates co-beta-track-aligned MD structures (e.g., 214) by at least distance gap_MD_ez, i.e., a benefit of using the fourth design rule, is that distance gap_MD_ez is easier to achieve/manufacture as compared to having to achieve/manufacture the counterpart distance gap_MD_min according to the other approach. Consequently, a Y-abutted arrangement based on cell region 204A enjoys resultant benefits including lower manufacturing costs, reduced time required to manufacture, improved performance (e.g., reliability), or the like, as compared to the other approach.

FIG. 2B is a table, in accordance with some embodiments.

The table of FIG. 2B summarizes relationships shown in FIG. 2A. More particularly, the table relates intersections of (A) alpha tracks α2-α(M−2) and (B) alternating ones of beta tracks β2-β6, i.e., even ones of beta tracks β2-β6, to corresponding locations 220-226. Abbreviating the words source and drain corresponding as S and D, the table also indicates how each of locations 220-226 correspondingly is configurable as follows: only as a source; or as a source or as a drain; or as neither a source nor as a drain.

FIGS. 2C-2D are layout diagrams of corresponding functional cell regions 204C-204D, in accordance with some embodiments.

Each of cell regions 204C and 204D is similar to cell region 204A of FIG. 2A. For purposes of brevity, the discussion will focus on differences of each of cell regions 204C and 204D as compared to cell region 204A rather than on similarities.

In the example of FIG. 2C, relative to the X-axis, a width of cell region 204C, w_204C, is equal to 3*p_gate such that w_204C=(3*p_gate), and such that w_204C<w_204A. In the example of FIG. 2D, relative to the X-axis, a width of cell region 204D, w_204D, is equal to 2*p_gate such that w_204D=(2*p_gate), and such that w_204D<w_204C<w_204A. In some embodiments, width w_204D represents the minimum width for a cell region that is compliant with the first to fourth design rules. In some embodiments, width w_204D represents the minimum width for a cell region that has locations 220-226.

In the example of FIG. 2C, the subject of the fourth design rule is the preantepenultimate beta track, e.g., beta track β4 in FIG. 2C. In the example of FIG. 2D, the subject of the fourth design rule is the preantepenultimate beta track, e.g., beta track β2 in FIG. 2D.

FIG. 3A is a layout diagram of a cell region 304A, in accordance with some embodiments.

Cell region 304A includes cell regions 204A(1) and 204A(2). Each of cell region 204A(1) and 204A(2) is an instance of cell region 204A of FIG. 2A. For improved clarity, the active region (AR) in cell region 204A(2) is labelled 206(2). Cell region 304A is compliant with the first to fourth design rules.

Cell region 304A is an example of a Y-abutted arrangement.

Relative to the Y-axis, cell region 204A(1) is abutted to cell region 204A(2) such that the last alpha track (e.g., αM) of cell region 204A(1) is substantially collinear with the first alpha track (e.g., α1) of cell region 204A(1) such that M0_PG segment 216 of the first instance of cell region 204A is shared by the second instance of cell region 204A.

FIG. 3B is a layout diagram of a macro region 302B, in accordance with some embodiments.

Macro region 302B is an example of an X-abutted arrangement in addition to being an example of a Y-abutted arrangement. Each of the twenty-four cell regions in macro region 302B is an instance of a version of cell region 204A of FIG. 2A; as a result, each of the cell regions of macro region 302B have the same height relative to the Y-axis and the same width relative to the Y-axis. The version of cell region 204A in FIG. macro region 302B replaces the IDGs with corresponding gate segments, which facilitates an X-abutted arrangement (discussed below).

In terms of Y-abutted arrangement, macro region 302B has three columns. Each column includes eight instances of cell region 204A abutted to each other. As such, macro region 302B is also described as including three rows. Each row includes three instances of instances of cell region 204A.

In terms of X-abutted arrangement, in each row of macro region 302B, a first instance of cell region 204A is abutted to a second instance of cell region 204 relative to the X-axis such that the last beta track (e.g., β9) of the first instance of cell region 204A is substantially collinear with the first beta track (e.g., β1) of the second instance of cell region 204A. As a result, the gate segment aligned to the last beta track (e.g., β9) of the first instance of cell region 204A is shared with gate segment aligned to the first beta track (e.g., β1) of the second instance of cell region 204A.

FIG. 3C is a layout diagram of a cell region 304C, in accordance with some embodiments.

Cell region 304A is an example of a Y-abutted arrangement. Cell region 304C includes cell regions 204D(1) and 204D(2). Each of cell region 204D(1) and 204D(2) is an instance of cell region 204D of FIG. 2D. Relative to the Y-axis, each of cell regions 204D(1) and 204D(2) has been rotated 180 degrees (180°). Also, each of cell regions includes: via-to-gate (VG) contacts over areas of the gate segments and under areas of the M0 segments; and via-to-MD (VD) contacts over areas of the MD structures and under areas of the M0 segments.

FIG. 4A is a layout diagram of a cell region 404A, in accordance with some embodiments.

Cell region 404A represents a CFET architecture. In some embodiments, cell region 404A is described as being based on a version of cell region 204A of FIG. 2A which has been adapted to the CFET architecture. In some embodiments, cell region 404A is described as being based on a version of cell region 204C of FIG. 2C which has been adapted to the CFET architecture. In some embodiments, the function of cell region 404A is a logical NAND operation. Cell region 404A is compliant with the first to fourth design rules.

FIG. 4A includes a reference line 440 which represents a reference plane which defines the front side and back side of cell region 404A. Cell region includes: a first portion representing a front side of cell region 404A, the first portion being referred to herein as front side 438A_fr; and a second portion 438A_bk representing a back side of cell region 404A, the second portion being referred to herein as back side 438A_bk.

Cell region 404A assumes a context in which front side 438A_fr is configured for NMOS transistors having an N-type active region such that the M1_PG segment is configured for VSS and back side 438A_bk is configured for PMOS transistors having a P-type active region such that the BM1_PG segment is configured for VDD. In some embodiments, cell region assumes the opposite context, i.e., PMOS for front side 438A_fr and NMOS for back side 438A_bk.

In FIG. 4A, relative to the Y-axis, the M0_PG segment and the M0_rte segments have substantially the same width w_M0_common. Relative to the X-axis, each of M1_PG segments has a width w_M1_PG and each of M1_rte segments has a width w_M1_rte. Width w_M1_PG is greater than width w_M1_rte such that w_M1_rte<w_M1_PG. Also, width w_M0_common is less than width w_M1_PG such that w_M0_common<w_M1_PG. In some embodiments, width w_M0_common is less than width w_M1_rte such that w_M0_common<w_M1_rte.

Also in FIG. 4A, relative to the Y-axis, the BM0_PG segment and the BM0_rte segments have substantially the same width w_BM0_common. Relative to the X-axis, each of BM1_PG segments has a width w_BM1_PG and each of BM1_rte segments has a width w_BM1_rte. Width w_BM1_PG is greater than width w_BM1_rte such that w_BM1_rte<w_BM1_PG. Also, width w_BM0_common is less than width w_BM1_PG such that w_BM0_common<w_BM1_PG. In some embodiments, width w_BM0_common is less than width w_BM1_rte such that w_BM0_common<w_BM1_rte. In some embodiments, w_BM0_common=w_M0_common.

Relative to the X-axis, each of the M1_PG segment and the BM1_PG segment overlaps beta tracks β1-β2. Relative to the X-axis, in some embodiments, the M1_PG segment and the BM1_PG segment are substantially colinear. In terms of front side versus back side (FB) symmetry relative to the beta tracks (FB_MBM1_β symmetry), in some embodiments, cell region 404A is described as FB_MBM1_β-symmetric because each of the M1_PG segment and the BM1_PG segment overlaps the same beta tracks, namely beta tracks β1-β2.

In some embodiments, a PG-arrangement of a cell region (e.g., 404A) is defined as the positions of the M1_PG segment and the BM1_PG segment relative to the X-axis. In some embodiments, the PG-arrangement of cell region 404A is described as a peripheral PG-arrangement because of the following: the M1_PG segment overlaps one or more of the beta tracks (beta tracks β1-β2 in FIG. 4A) which overlap a peripheral area (i.e., left-side area) of cell region 404A; and the BM1_PG segment overlaps one or more of the beta tracks (beta tracks β1-β2 in FIG. 4A) which overlap a peripheral area (i.e., left-side area) of cell region 404A.

FIG. 4B is a layout diagram of a cell region 404B, in accordance with some embodiments.

Cell region 404B represents a CFET architecture. In some embodiments, cell region 404B is described as being based on a version of cell region 204C of FIG. 2C which has been adapted to the CFET architecture. Cell region 404B is similar to cell region 404A of FIG. 4A. Cell region 404B is compliant with the first to fourth design rules. In some embodiments, the function of cell region 404B is a logical AOI operation. For purposes of brevity, the discussion will focus on differences of cell region 404B as compared to cell region 404A rather than on similarities.

Relative to the X-axis, each of the M1_PG segment and the BM1_PG segment overlaps beta tracks β3-β4. Relative to the X-axis, in some embodiments, the M1_PG segment and the BM1_PG segment are substantially colinear. In terms FB_MBM1_β symmetry, in some embodiments, cell region 404B is described as FB_MBM1_β-symmetric because each of the M1_PG segment and the BM1_PG segment overlaps the same beta tracks, namely beta tracks β3-β4.

In some embodiments, the PG-arrangement of cell region 404B is described as a central PG-arrangement because of the following: the M1_PG segment overlaps one or more of the beta tracks (beta tracks β3-β4 in FIG. 4B) which overlap a central area of cell region 404B; and the BM1_PG segment overlaps one or more of the beta tracks (beta tracks β3-β4 in FIG. 4B) which overlap the central area of cell region 404B.

FIG. 4C is a layout diagram of a cell region 404C, in accordance with some embodiments.

Cell region 404C represents a CFET architecture. In some embodiments, cell region 404C is described as being based on a version of cell region 404A of FIG. 4A; as such, cell region 404C is similar to cell region 404A of FIG. 4A. Cell region 404C is compliant with the first to fourth design rules. In some embodiments, the function of cell region 404C is a logical NAND operation. For purposes of brevity, the discussion will focus on differences of cell region 404C as compared to cell region 404A rather than on similarities.

Relative to the X-axis, while the M1_PG segment overlaps beta tracks β1-β2, the BM1_PG segment overlaps beta tracks β5-β6. Relative to the X-axis, more generally, the M1_PG segment overlaps a first set of one or more of the beta tracks which is different than a second set of one or more of the beta tracks overlapped by the BM1_PG segment. In the example of FIG. 4C, the first and second sets do not intersect, i.e., there is beta track which is member of each of the first and second set. In terms FB_MBM1_β symmetry, in some embodiments, cell region 404C is described as FB_MBM1_β-asymmetric because the M1_PG segment overlaps the first set of beta tracks, namely beta tracks β1-β2, and the BM1_PG segment overlaps the different second set of beta tracks, namely beta tracks β5-β6.

In some embodiments, the PG-arrangement of cell region 404C is described as a peripheral PG-arrangement because of the following: the M1_PG segment overlaps one or more of the beta tracks (beta tracks β1-β2 in FIG. 4C) which overlap a central area of cell region 404C; and the BM1_PG segment overlaps one or more of the beta tracks (beta tracks β5-β6 in FIG. 4C) which overlap the central area of cell region 404C.

In some embodiments, the PG-arrangement of cell region 404C is described as a peripheral PG-arrangement because of the following: the M1_PG segment overlaps the first set of beta tracks (beta tracks β1-β2 in FIG. 4C), and the first set overlap a peripheral area (i.e., left-side area) of cell region 404C; and the M1_PG segment overlaps one or more of the beta tracks (beta tracks β5-β6 in FIG. 4C) which overlap proximal to a peripheral area (i.e., right-side area) and to the central area of cell region 404C.

FIG. 4D is a cross-section of a cell region 404D, in accordance with some embodiments.

In some embodiments, cell region 404D FIG. 4D is an example of cell region 404C of FIG. 4C. Cross-section 404D corresponds to section lines 4D-4D′ of FIG. 2C.

Various layers are shown in FIG. 4D. In addition to the layers in FIG. 4D noted above, FIG. 4D includes the following: a VG/VD layer; a Gate/MD layer; an AR_N layer; an AR_P layer; a BGate/BMD layer; and a BVG/BVD layer. The BGate/BMD layer includes buried gate (bgate segments) and buried MD (BMD) structures. The BVG/BVD layer includes buried VG (BVG) contacts and buried VD (BVD) contacts.

FIG. 5A is a layout diagram of a cell region 504A, in accordance with some embodiments.

Cell region 504A represents a CFET architecture having front side 538A_fr and back side 538A_bk. In some embodiments, cell region 504B is described as being based on a version of cell region 204A of FIG. 2A which has been adapted to the CFET architecture. Cell region 504A is compliant with the first to fourth design rules. In some embodiments, the function of cell region 504B is a flip-flop, e.g., an SDFQ. For purposes of brevity, the discussion will focus on differences of cell region 504B as compared to cell region 504A rather than on similarities.

FIG. 5B is a layout diagram of a cell region 504B, in accordance with some embodiments.

Cell region 504B represents a CFET architecture having front side 538B_fr and back side 538B_bk. In some embodiments, cell region 504B is described as being an alternate arrangement of cell region 504A of FIG. 5A; as such, cell region 504B is described as being based on a version of cell region 204A of FIG. 2A which has been adapted to the CFET architecture. Cell region 504B is compliant with the first to fourth design rules. In some embodiments, the function of cell region 504B is a flip-flop, e.g., an SDFQ.

FIG. 5C is a layout diagram of a cell region 504C, in accordance with some embodiments.

Cell region 504C represents a CFET architecture having front side 538C_fr and back side 538C_bk. In some embodiments, cell region 504C is described as being an alternate arrangement of cell region 504B of FIG. 5B; as such, cell region 504C is described as being based on a version of cell region 204A of FIG. 2A which has been adapted to the CFET architecture. Cell region 504C is compliant with the first to fourth design rules. In some embodiments, the function of cell region 504C is a flip-flop, e.g., an SDFQ.

FIG. 5D is a layout diagram of a cell region 504D, in accordance with some embodiments.

Cell region 504D represents a CFET architecture having front side 538D_fr and back side 538D_bk. In some embodiments, cell region 504D is described as being an alternate arrangement of cell region 504B of FIG. 5C; as such, cell region 504D is described as being based on a version of cell region 204A of FIG. 2A which has been adapted to the CFET architecture. In some embodiments, cell region 504D is described as being an alternate arrangement of cell region 504A of FIG. 5A. Cell region 504D is compliant with the first to fourth design rules. In some embodiments, the function of cell region 504D is a flip-flop, e.g., an SDFQ.

FIGS. 5E-5F are layout diagrams of Y-abutted arrangements of various functional cell regions, in accordance with some embodiments.

In FIGS. 5E-5F, the Y-abutted arrangements represent a CFET architecture. For simplicity of illustration, the Y-abutted arrangements of FIGS. 5E-5F show one side of the CFET architecture. In some embodiments, the Y-abutted arrangements of FIGS. 5E-5F represent the front side of the CFET architecture. In some embodiments, the Y-abutted arrangements of FIGS. 5E-5F represent the back side of the CFET architecture. In FIGS. 5E-5F, each of the various cell regions is compliant with the first to fourth design rules.

In FIG. 5E, the Y-abutted arrangement includes an AOI cell region 504E(1), an inverter cell region 504E(2), a NAND cell region 504E(3), an AOI cell region 504E(1) and a MUX cell region 504E(4). In FIG. 5F, the Y-abutted arrangement includes an AOI cell region 504F(1) and inverter cell region 504E(2). In some embodiments, AOI cell region 504F(1) of FIG. 5F is described as being an alternate arrangement of AOI cell region 504E(1) of FIG. 5E.

Relative to the X-axis, AOI cell region 504F(1) of FIG. 5F aligns differently with respect to inverter cell region 504E(2) than how AOI cell region 504E(1) of FIG. 5E aligns with respect to inverter cell region 504E(2). In other words, AOI cell region 504F(1) of FIG. 5F is shifted along the X-axis with respect to inverter cell region 504E(2) as compared to the alignment of AOI cell region 504E(1) of FIG. 5E with respect to inverter cell region 504E(2).

FIG. 5G is a layout diagram of a macro region 502G, in accordance with some embodiments.

Macro region 502G is an example of Y-abutted arrangement and an X-abutted arrangement. Macro region 502G includes various cell regions. Included among the various cell regions are two instances of an inverter cell region 504G(1), a NAND cell region 504G(2) and a NAND cell region 504G(3).

The various cell regions of macro region 502G have different heights relative to the Y-axis and different widths relative to the X-axis.

The preceding discussion of the first to fourth design rules assumed a macro region (e.g., 302B) in which all cell regions have the same width relative to the X-axis and thus each cell region has the same number of MD-aligned tracks. Accordingly, the previous discussion of the first to fourth design rules was expressed in terms of a uniform number of MD-aligned beta tracks per cell region.

Because of the differing widths of the various cell regions in macro region 502G, application of the first to fourth design rules to macro region 502G has adapted the first to fourth design rules to be expressed in terms of a repeating cycle (or pattern or sequence) of a P number of MD-aligned beta tracks, where P is a positive integer and 2≤P, or alternatively in terms of a repeating cycle of Q number of beta tracks, where Q is a positive integer and Q=2*P.

Macro region 502G has beta tracks β1-β25 of which the even-numbered beta tracks are MD-aligned beta tracks. In the example of macro region 502G, P=4. In the example of macro region 502G, the cycle includes P=4 MD-aligned beta tracks, i.e., the cycle repeats every P=4 MD-aligned beta tracks. Alternatively, in the example of macro region 502G, Q=8, i.e., the cycle repeats every Q=8 beta tracks. In the example of FIG. 5G, the first cycle concerns beta tracks β2-β9, the second cycle concerns beta tracks β10-β17, the third cycle concerns beta tracks β18-β25, and so forth.

The fourth design rule is directed to fourth locations 526, only some of which have reference number 526 in FIG. 5G for simplicity of illustration. In the context of macro region 502G, the fourth design rule dictates: fourth locations 526 are at the intersections of (A) alpha tracks α1 and αM and (B) beta tracks β2, β10 and β18; and the corresponding overlapped region of an active region (e.g., 206(1)) at each instance of fourth locations 526 is free of being configurable as a source region or a drain region, i.e., is not to be configured as a source region nor as a drain region.

In the example of macro region 502G, each of the first to third design rules is adapted to the P=4 cycle, i.e., to the Q=8 cycle, in a correspondingly similar manner to the adaptation of the fourth design rule. The first design rule is directed to first locations 520, only some of which have reference number 520 in FIG. 5G for simplicity of illustration. The second design rule is directed to second locations 522, only some of which have reference number 522 in FIG. 5G for simplicity of illustration. The third design rule is directed to third locations 524, only some of which have reference number 524 in FIG. 5G for simplicity of illustration.

In some embodiments, the first to fourth design rules are restated as fifth and sixth design rules. Locations 522 and 526 are the subjects of the fifth design rule. Locations 520 and 522 are the subjects of the sixth design rule.

The fifth design rule states that locations 522 and 526 are to be aligned to a same one of beta tracks β2, β10 or β18. In FIG. 5G, beta tracks β2, β10 or β18 are assumed to be the beta tracks which are the subject of the fifth design rule.

The sixth design rule states: an instance of location 520 and an instance of location 522 can be aligned to a one of beta tracks β1, β3-β9, β11-β17, or β19-β25; an instance of location 520 is free from being aligned to a same beta track to which an instance of location 524 or an instance of location 526 is aligned; and an instance of location 522 is free from being aligned to a same beta track to which an instance of location 524 or an instance of location 526 is aligned. In other words, the sixth design rule states: an instance of location 520 and an instance of location 522 can be aligned to the same beta track; an instance of location 520 cannot be aligned to a same beta track as an instance of location 524 or an instance of location 526; and an instance of location 522 cannot be being aligned to a same beta track as an instance of location 524 or an instance of location 526 is aligned.

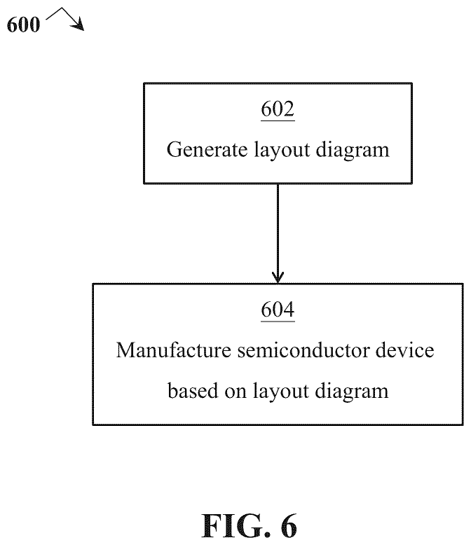

FIG. 6 is a flowchart (flow diagram) of a method 600 of manufacturing device, in accordance with some embodiments.

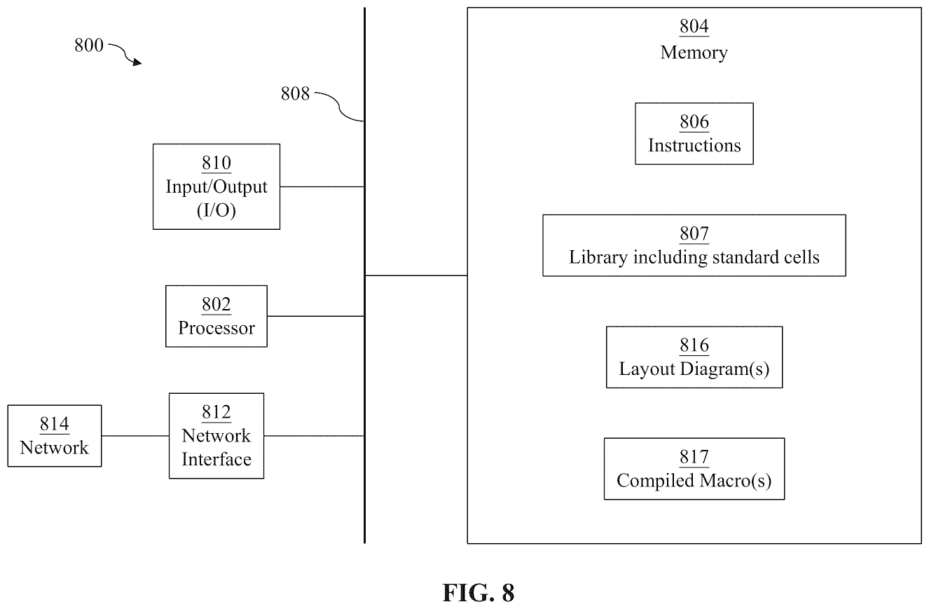

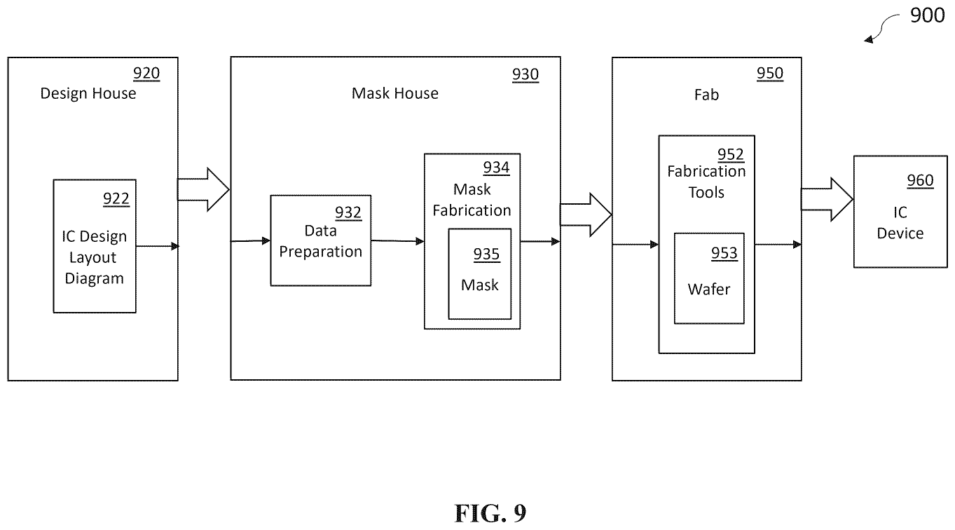

Method 600 is implementable, for example, using EDA system 800 (FIG. 8, discussed below) and an IC manufacturing system 900 (FIG. 9, discussed below), in accordance with some embodiments. Examples of cell regions and/or macro regions which can be manufactured according to method 600 include the cell regions and/or macro regions disclosed herein, or the like.

In FIG. 6, method 600 includes blocks 602-604. At block 602, a layout diagram is generated which, among other things, includes one or more layout diagrams corresponding to one or more of the cell regions herein, one or more of the macro regions disclosed herein, or the like. Block 602 is implementable, for example, using EDA system 800 (FIG. 8, discussed below), in accordance with some embodiments. From block 602, flow proceeds to block 604.

At block 604, based on the layout diagram, at least one of (A) one or more photolithographic exposures are made or (b) one or more photolithography masks are fabricated or (C) one or more components in a layer of a device, e.g., a device is fabricated. See discussion below of IC manufacturing system 900 in FIG. 9 below.

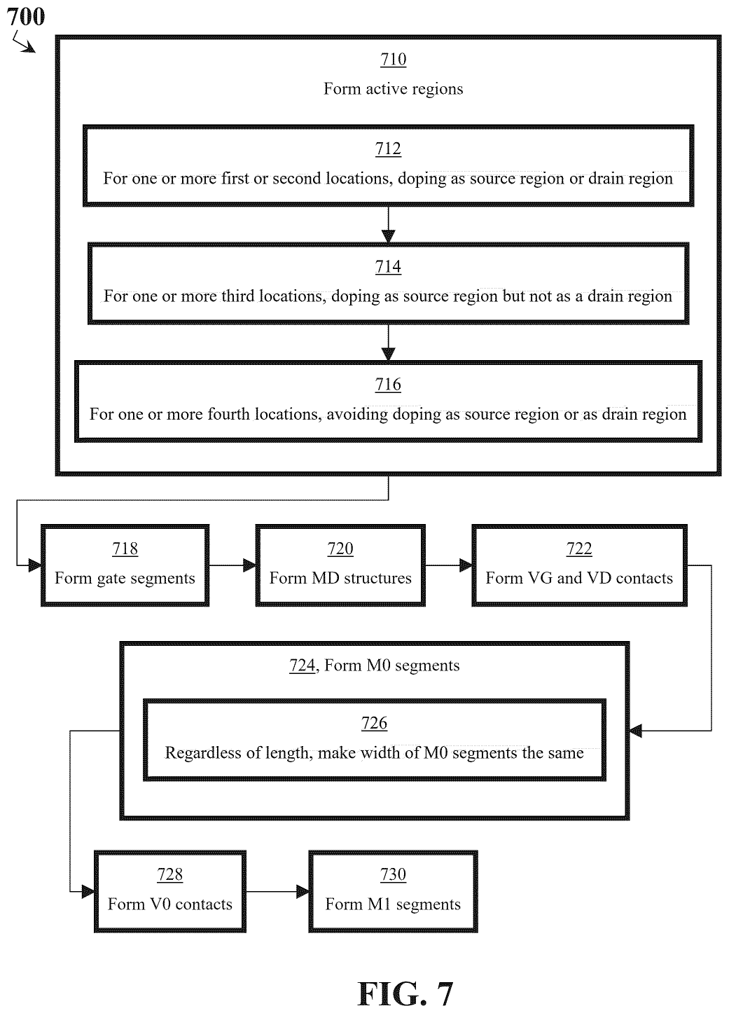

FIG. 7 is a flowchart of a method 700 of manufacturing a device, in accordance with some embodiments.

Method 700 is an example of block 604 (see FIG. 6, discussed above). Method 700 is implementable, for example, using IC manufacturing system 900 (see FIG. 9, discussed below), in accordance with some embodiments. Examples of a devices which can be manufactured according to method 700 include devices that include one or more of cell regions disclosed herein or one or more of the macro regions disclosed herein, or the like. Method 700 includes blocks 710-730.

At block 710, active regions active regions (e.g., 206(1)) are formed extending in a first direction (e.g., parallel to the X-axis). Block 710 includes blocks 712-716 that are directed to at least a first one of the active regions (e.g., 206(1)). Within block 710, flow proceeds to block 712.

At block 712, for one or more first locations (e.g., 220) or second locations (e.g., 222), an MD-overlapped region of a corresponding active region is doped as a source region or as a drain region. An MD-overlapped region of an active region is a region of an active region that will be overlapped by a subsequently formed MD structure (e.g., 214). Regarding doping of the first locations (e.g., 220), see the discussion above regarding the first design rule. Regarding doping of the second locations (e.g., 222), see the discussion above regarding the second design rule. From block 712, flow proceeds to block 714.

At block 714, for one or more third locations (e.g., 224), an MD-overlapped region of a corresponding active region is doped as a source region but not as a drain region. Regarding doping of the third locations (e.g., 224), see the discussion above regarding the third design rule. From block 714, flow proceeds to block 716.

At block 716, for one or more fourth locations (e.g., 226), an MD-overlapped region of a corresponding active region doping as a source region or as a drain region is avoided. That is, for one or more fourth locations (e.g., 226), action is taken to avoid doping an MD-overlapped region of a corresponding active region as a source region or as a drain region. Regarding avoiding doping the fourth locations (e.g., 226), see the discussion above regarding the fourth design rule. From block 716, flow proceeds to block 718.

At block 718, gate segments (e.g., 210) are formed which extend in a second direction (e.g., parallel to the Y-axis) perpendicular to the first direction, are interspersed with MD structures (subsequently formed (see block 720)), and have portions over areas of the active regions. From block 718, flow proceeds to block 720.

At block 720, MD structures (e.g., 214) are formed which extend in the second direction, are interspersed with the gate segments, and have portions over areas of the active regions. From block 720, flow proceeds to block 722.

At block 722, VG contacts (e.g., see FIG. 3C) are formed over areas of the gate segments and VD contacts (e.g., see FIG. 3C) are formed over areas of the MD structures. From block 722, flow proceeds to block 724.

At block 724, in a first layer of metallization (e.g., see layer MET0 of FIG. 4D), M0 segments (e.g., 216, 218) are formed which extend in the first direction (e.g., parallel to the X-axis), and are aligned correspondingly to the alpha tracks (e.g., see α0, α1, . . . ). The M0 segments include one or more M0_PG segments (e.g., 216) and one or more M0_rte segments (e.g., 218). Block 724 includes block 726. Within block 724, flow proceeds to block 726.

At block 726, each of the M0 segments (e.g., 216, 218) is sized to have the same width relative to the Y-axis, regardless of length relative to the X-axis. In other words, at block 726, the one or more M0_PG segments (e.g., 216) is sized to have the same width (e.g., w_M0_common) as the one or more M0_rte segments (e.g., 218). From block 726, flow proceeds to block 728.

At block 728, V0 structures (e.g., see FIG. 4D) are formed over areas of the M0 segments. From block 728, flow proceeds to block 730.

At block 730, in a second layer of metallization (e.g., see layer MET1 of FIG. 4D), M1 segments (e.g., 230(1)-230(2)) are formed which extend in the second direction (e.g., parallel to the Y-axis). The M1 segments include one or more M1_PG segments (e.g., 230(1)-230(2)) and one or more M0_rte segments (e.g., 232).

Regarding a CFET architecture, in some embodiments, blocks 710-730 are performed iteratively. In some embodiments, a first iteration of blocks 710-730 is performed for a front side of the CFET architecture, and then a second of blocks 710-730 is performed for a back side of the CFET architecture. As the second iteration is directed to the back side of the CFET architecture, during the second iteration, the following is true: block 710 forms BM0 segments (e.g., see FIGS. 4A-4D) rather than M0 segments; block 718 forms bgate segments rather than gate segments; block 720 forms BMD structures rather than MD structures; block 722 forms BVG contacts and BVD contacts rather than VG contacts and VD contacts; block 724 forms BM0 segments rather than M0 segments; block 728 forms BV0 structures rather than V0 structures; and block 730 forms BM1 segments rather than M1 segments.

Regarding a CFET architecture, in some embodiments, a result of the first and second iterations is that a corresponding cell region is FB_MBM1_β-symmetric (e.g., see FIGS. 4A-4B) or is FB_MBM1_β-asymmetric (e.g., see FIG. 4C).

Regarding a CFET architecture, in some embodiments, a result of the first and second iterations is that a corresponding cell region has a peripheral PG-arrangement (e.g., see FIGS. 4A and 4C) or a central PG-arrangement (e.g., see FIG. 4B).

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a processor 802 (e.g., a hardware processor) and a non-transitory, computer-readable storage medium 804. Storage medium 804, amongst other things, is encoded with, i.e., stores, computer program code 806, i.e., a set of executable instructions. Execution of instructions 806 by processor 802 represents (at least in part) an EDA tool which implements a portion of or all, e.g., one or more methods of generating layout diagrams corresponding to the layout diagrams disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and storage medium 804 are capable of connecting to external elements via network 814. Processor 802 is configured to execute computer program code 806 encoded in storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, storage medium 804 is an electronic, magnetic, optical, electromagnetic, infrared, and/or a semiconductor system (or apparatus or device). For example, storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, storage medium 804 includes a compact disk-read only memory (CD-ROM), a compact disk-read/write (CD-R/W), and/or a digital video disc (DVD).

In one or more embodiments, storage medium 804 stores instructions, i.e., computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the layout diagrams disclosed herein. Storage medium 804 stores one or more layout diagrams 816 such as one or more layout diagrams corresponding to the layout diagrams disclosed herein, one or more compiled macros 817 based on layout diagrams including one or more of the layout diagrams disclosed herein, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 702 of FIG. 7, the IC manufacturing system 900 implements block 704 of FIG. 7 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 5, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a cell region (of a device) includes: a first active region (AR) extending in a first direction; first metal-to-source/drain contact (MD) structures extending in a second direction perpendicular to the first direction and aligning to beta tracks; in a first metallization layer, segments extending in the first direction and aligning to alpha tracks; and for one or more first or second locations, a corresponding region of the first AR being configurable as a source region or a drain region; for one or more third locations, a corresponding region of the first AR being configurable as a source region, regions of the first AR at the third locations being free of being configurable as a drain region; for one or more fourth locations, a corresponding region of the AR being free from being configurable as a source region or a drain region; each of the first to fourth locations being at an intersection of (A) a corresponding one of the alpha tracks and (B) a corresponding one of the beta tracks; first and last ones of the beta tracks substantially aligning correspondingly to left and right boundaries of the cell region; and the first and last alpha tracks substantially aligning correspondingly to top and bottom boundaries of the cell region.

In some embodiments, the first AR has a first type of conductivity; the cell region further comprises a second AR extending in the first direction and having a second type of conductivity different than the first type of conductivity; the cell region has a complimentary field-effect transistor (CFET) architecture including as follows, the first AR being aligned with the second AR relative to the first and second directions, and the first AR being stacked over the second AR relative to a third direction perpendicular to each of the first and second directions; the first and second ARs being separated by a first gap relative to the third direction, the first gap being divided by a reference plane relative to the third direction; the first MD structures and the first metallization layer are over the reference plane; the cell region further includes as follows, second MD structures extending in the second direction, aligning to the beta tracks and being under the reference plane, and in a first metallization (BM_1st layer) under the reference plane, segments extending in the first direction and aligning to the alpha tracks; and at one or more of the first or second locations, a corresponding region of the second AR is configurable as a source region or a drain region; at one or more of the third locations, a corresponding region of the second AR is configurable as a source region; and at one or more of the fourth locations, a corresponding region of the second AR is free from being configurable as a source region or a drain region.

In some embodiments, in the first metallization layer (M_1st layer), relative to the second direction, each of the segments has substantially a same width; in the M_1st layer, a first one of the segments aligns with the first alpha track and is a first power grid (PG) segment (first M_1st_PG segment), the first M_1st_PG segment being configured for a first reference voltage; and the first M_1st_PG segment is a rail that extends continuously (i) between the left and right boundaries of the cell region and (ii) beyond each of the left and right boundaries of the cell region.

In some embodiments, in the BM_1st layer, relative to the second direction, each of the segments has substantially a same width; in the BM_1st layer, a first one of the segments aligns with the first alpha track and is a first PG segment (first BM_1st_PG segment), the first BM_1st_PG segment being configured for a second reference voltage different than the first reference voltage; and the first BM_1st_PG segment is a rail that extends continuously (i) between the left and right boundaries of the cell region and (ii) beyond each of the left and right boundaries of the cell region.

In some embodiments, in the first metallization layer (M_1st layer), a first one of the segments is a first power grid (PG) segment (first M_1st_PG segment), the first M_1st_PG segment being configured for a first reference voltage; in the BM_1st layer, a first one of the segments is a first PG segment (first BM_1st_PG segment), the first BM_1st_PG segment being configured for a second reference voltage different than the first reference voltage; in a second metallization (M_2nd layer) over the M_1st layer, the cell region further comprises segments (M_2nd segments) extending in the second direction; a first one of the M_2nd segments is a first PG segment (first M_2nd_PG segment) that is configured for the first reference voltage; the first M_2nd_PG segment is coupled to the first M_1st_PG segment; in a second metallization (BM_2nd layer) under the BM_1st layer, the cell region further comprises segments (BM_2nd segments) extending in the second direction; a first one of the BM_2nd segments is a first PG segment (first BM_2nd_PG segment) that is configured for the second reference voltage; the first BM_2nd_PG segment is coupled to the first BM_1st_PG segment; and relative to the first direction, the first M_2nd_PG segment and the first BM_2nd_PG segment overlap a same one of the beta tracks.

In some embodiments, regarding the beta track which is overlapped by each of the first M_2nd_PG segment and the first BM_2nd_PG segment, and relative to the first direction, the beta track intersects a central area of the cell region.

In some embodiments, regarding the beta track is overlapped by each of the first M_2nd_PG segment and the first BM_2nd_PG segment, and relative to the first direction, the beta track is proximal to the left boundary or the right boundary of the cell region such that each of the first M_2nd_PG segment and the first BM_2nd_PG segment overlaps the left boundary or the right boundary of the cell region.

In some embodiments, in the first metallization layer (M_1st layer), a first one of the segments is a first power grid (PG) segment (first M_1st_PG segment), the first M_1st_PG segment being configured for a first reference voltage; in the BM_1st layer, a first one of the segments is a first PG segment (first BM_1st_PG segment), the first BM_1st_PG segment being configured for a second reference voltage different than the first reference voltage; in a second metallization (M_2nd layer) over the M_1st layer, the cell region further comprises segments (M_2nd segments) extending in the second direction; a first one of the M_2nd segments is a first PG segment (first M_2nd_PG segment) that is configured for the first reference voltage; the first M_2nd_PG segment is coupled to the first M_1st_PG segment; in a second metallization (BM_2nd layer) under the BM_1st layer, the cell region further comprises segments (BM_2nd segments) extending in the second direction; a first one of the BM_2nd segments is a first PG segment (first BM_2nd_PG segment) that is configured for the second reference voltage; the first BM_2nd_PG segment is coupled to the first BM_1st_PG segment; relative to the first direction, the first M_2nd_PG segment and the first BM_2nd_PG segment overlap different ones of the beta tracks.

In some embodiments, regarding the different beta tracks which are correspondingly overlapped by the first M_2nd_PG segment and the first BM_2nd_PG segment, and relative to the first direction, the beta track which is overlapped by the first M_2nd_PG segment is also proximal to the left boundary or the right boundary of the cell region and the beta track which is overlapped by the first BM_2nd_PG segment is also proximal correspondingly to the right boundary or left boundary of the cell region such that the first M_2nd_PG segment overlaps the left boundary or the right boundary of the cell region and the first BM_2nd_PG segment correspondingly overlaps the right boundary or left boundary of the cell region.

In some embodiments, regarding the different beta tracks which are correspondingly overlapped by the first M_2nd_PG segment and the first BM_2nd_PG segment, and relative to the first direction, the first M_2nd_PG segment and the first BM_2nd_PG segment are spaced apart from each other correspondingly towards the left and right boundaries or the right and left boundaries such that a central area of the cell region is free from being overlapped by each of the first M_2nd_PG segment and the first BM_2nd_PG segment.

In some embodiments, the first locations are at intersections of (A) second through antepenultimate ones of the alpha tracks and (B) alternating second through preantepenultimate ones of the beta tracks, and the second locations are at intersections of (A) the second through penultimate alpha tracks and (B) a penultimate one of the beta tracks; the third locations are at intersections of (E) first and last ones of the alpha tracks and (F) the alternating second through preantepenultimate beta tracks, and the fourth locations are at intersections of (A) the first and last alpha tracks and (B) the penultimate beta track.

In some embodiments, a device includes first and second cell regions each of which includes: a first active region (AR) extending in a first direction; first metal-to-source/drain contact (MD) structures extending in a second direction perpendicular to the first direction and aligning to beta tracks; in a first metallization layer, segments therein (M_1st segments) extending in the first direction and aligning to alpha tracks; and for one or more first or second locations, a corresponding region of the first AR being configurable as a source region or a drain region; for one or more third locations, a corresponding region of the first AR being configurable as a source region, regions of the first AR at the third locations being free of being configurable as a drain region; for one or more fourth location, a corresponding region of the AR being free from being configurable as a source region or a drain region; each of the first to fourth locations being at an intersection of (A) a corresponding one of the alpha tracks and (B) a corresponding one of the beta tracks; first and last ones of the beta tracks substantially aligning correspondingly to left and right boundaries of the cell region; the first and last alpha tracks substantially aligning correspondingly to top and bottom boundaries of the cell region; relative to the second direction, the first cell region being stacked on the second cell region; for each of the first and second cell regions, one or more ones of the M_1st segments aligned to the first alpha track are also overlapping the top boundary, and the last alpha track of the first cell region is substantially collinear with the first alpha track of the second cell region such that the one or more ones of the M_1st segments aligned to the first alpha track of the second cell region are shared by the first cell region.

In some embodiments, for each of the first and second cell regions, the first AR has a first type of conductivity; each of the first and second cell regions further comprises a second AR extending in the first direction and having a second type of conductivity different than the first type of conductivity; each of the first and second cell regions has a complimentary field-effect transistor (CFET) architecture including as follows, the first AR being aligned with the second AR relative to the first and second directions, and the first AR being stacked over the second AR relative to a third direction perpendicular to each of the first and second directions; the first and second ARs being separated by a first gap relative to the third direction, the first gap being divided by a reference plane relative to the third direction; the first MD structures and the first metallization layer are over the reference plane; each of the first and second cell regions further comprises as follows, second MD structures extending in the second direction, aligning to the beta tracks and being under the reference plane, and in a first metallization (BM_1st layer) under the reference plane, segments (BM_1st segments) extending in the first direction and aligning to the alpha tracks; and for each of the first and second cell regions, at one or more of the first or second locations, a corresponding region of the second AR is configurable as a source region or a drain region, at one or more of the third locations, a corresponding region of the second AR is configurable as a source region, and at one or more of the fourth locations, a corresponding region of the second AR is free from being configurable as a source region or a drain region; for each of the first and second cell regions, one or more ones of the BM_1st segments aligned to the first alpha track are also overlapping the top boundary, and one or more ones of the BM_1st segments aligned to the first alpha track of the second cell region are shared by the first cell region.

In some embodiments, a method (of forming a cell region of a device) includes: forming a first active region (AR) that extend in a first direction; forming first metal-to-source/drain contact (MD) structures that extend in a second direction perpendicular to the first direction and align to beta tracks; forming segments (M_1st segments) in a first metallization layer (M_1st layer) that extend in the first direction and align to alpha tracks; and the forming a first active region (AR) including as follows, for one or more first or second locations, doping a corresponding region of the first AR as a source region or a drain region; for one or more third locations, doping a corresponding region of the first AR as a source region, regions of the first AR at the third locations being free of being configurable as a drain region; for one or more fourth locations, avoiding a corresponding region of the AR being doped as a source region or a drain region; each of the first to fourth locations being at an intersection of (A) a corresponding one of the alpha tracks and (B) a corresponding one of the beta tracks; first and last ones of the beta tracks substantially aligning correspondingly to left and right boundaries of the cell region; and the first and last alpha tracks substantially aligning correspondingly to top and bottom boundaries of the cell region.

In some embodiments, the forming a first active region (AR) further includes doping the first AR to have a first type of conductivity, the method further includes forming a second AR that extends in the first direction; the forming a second AR includes doping the second AR to have a second type of conductivity different than the first type of conductivity; the method further includes arranging the cell region to have a complimentary field-effect transistor (CFET) architecture including as follows, aligning the first AR with the second AR relative to the first and second directions, and stacking the first AR over the second AR relative to a third direction perpendicular to each of the first and second directions, resulting in the first and second ARs being separated by a first gap relative to the third direction, the first gap being divided by a reference plane relative to the third direction, and the first MD structures and the first metallization layer being over the reference plane; under the reference plane, forming second MD structures that extend in the second direction and align to the beta tracks, and forming segments (BM_1st segments) in a first metallization (BM_1st layer) under the reference plane that extend in the first direction and align to the alpha tracks; and he forming a second AR includes as follows, for one or more of the first or second locations, doping a corresponding region of the second AR as a source region or a drain region, for one or more of the third locations, doping a corresponding region of the second AR as a source region; and for one or more of the fourth locations, avoiding a corresponding region of the second AR being doped as a source region or a drain region.

In some embodiments, a first one of the M_1st segments is a first power grid (PG) segment (first M_1st_PG segment), the first M_1st_PG segment being configured for a first reference voltage; a first one of the BM_1st segments is a first PG segment (first BM_1st_PG segment), the first BM_1st_PG segment being configured for a second reference voltage different than the first reference voltage; the method further includes forming segments (M_2nd segments) in a second metallization (M_2nd layer) over the M_1st layer that extend in the second direction, a first one of the M_2nd segments being a first PG segment (first M_2nd_PG segment) that is configured for the first reference voltage; and coupling the first M_2nd_PG segment to the first M_1st_PG segment; and the arranging the cell region to have a complimentary field-effect transistor (CFET) architecture further including as follows, forming segments (BM_2nd segments) in a second metallization (BM_2nd layer) under the BM_1st layer that extend in the second direction, a first one of the BM_2nd segments being a first PG segment (first BM_2nd_PG segment) that is configured for the second reference voltage; coupling the first BM_2nd_PG segment to the first BM_1st_PG segment; and relative to the first direction, locating the first M_2nd_PG segment and the first BM_2nd_PG segment overlap a same one of the beta tracks.

In some embodiments, the arranging the cell region to have a complimentary field-effect transistor (CFET) architecture further includes: regarding the beta track which is overlapped by each of the first M_2nd_PG segment and the first BM_2nd_PG segment, and relative to the first direction, locating the beta track to intersect a central area of the cell region.

In some embodiments, the arranging the cell region to have a complimentary field-effect transistor (CFET) architecture further includes: regarding the beta track is overlapped by each of the first M_2nd_PG segment and the first BM_2nd_PG segment, and relative to the first direction, locating the beta track to be proximal to the left boundary or the right boundary of the cell region such that each of the first M_2nd_PG segment and the first BM_2nd_PG segment overlaps the left boundary or the right boundary of the cell region.

In some embodiments, a first one of the M_1st segments is a first power grid (PG) segment (first M_1st_PG segment), the first M_1st_PG segment being configured for a first reference voltage; a first one of the BM_1st segments is a first PG segment (first BM_1st_PG segment), the first BM_1st_PG segment being configured for a second reference voltage different than the first reference voltage; the method further includes: forming segments (M_2nd segments) in a second metallization (M_2nd layer) over the M_1st layer that extend in the second direction, a first one of the M_2nd segments being a first PG segment (first M_2nd_PG segment) that is configured for the first reference voltage; and coupling the first M_2nd_PG segment to the first M_1st_PG segment; and the arranging the cell region to have a complimentary field-effect transistor (CFET) architecture further including as follows, forming segments (BM_2nd segments) in a second metallization (BM_2nd layer) under the BM_1st layer that extend in the second direction, a first one of the BM_2nd segments being a first PG segment (first BM_2nd_PG segment) that is configured for the second reference voltage; coupling the first BM_2nd_PG segment to the first BM_1st_PG segment; and relative to the first direction, locating the first M_2nd_PG segment and the first BM_2nd_PG segment differently so that the first M_2nd_PG segment and the first BM_2nd_PG segment overlap different ones of the beta tracks.

In some embodiments, the first locations are at intersections of (A) second through antepenultimate ones of the alpha tracks and (B) alternating second through preantepenultimate ones of the beta tracks, and the second locations are at intersections of (A) the second through penultimate alpha tracks and (B) a penultimate one of the beta tracks; the third locations are at intersections of (E) first and last ones of the alpha tracks and (F) the alternating second through preantepenultimate beta tracks; and the fourth locations being at intersections of (A) the first and last alpha tracks and (B) the penultimate beta track.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A cell region of a device, the cell region comprising:
a first active region (AR) extending in a first direction;
first metal-to-source/drain contact (MD) structures extending in a second direction perpendicular to the first direction and aligning to beta tracks;
in a first metallization layer, segments extending in the first direction and aligning to alpha tracks; and
for one or more first or second locations, a corresponding region of the first AR being configurable as a source region or a drain region;
for one or more third locations, a corresponding region of the first AR being configurable as a source region,
regions of the first AR at the third locations being free of being configurable as a drain region;
for one or more fourth locations, a corresponding region of the AR being free from being configurable as a source region or a drain region;
each of the first to fourth locations being at an intersection of (A) a corresponding one of the alpha tracks and (B) a corresponding one of the beta tracks;
first and last ones of the beta tracks substantially aligning correspondingly to left and right boundaries of the cell region; and
the first and last alpha tracks substantially aligning correspondingly to top and bottom boundaries of the cell region.

2. The cell region of claim 1, wherein:
the first AR has a first type of conductivity;
the cell region further comprises a second AR extending in the first direction and having a second type of conductivity different than the first type of conductivity;
the cell region has a complimentary field-effect transistor (CFET) architecture including as follows,
the first AR being aligned with the second AR relative to the first and second directions, and
the first AR being stacked over the second AR relative to a third direction perpendicular to each of the first and second directions;
the first and second ARs being separated by a first gap relative to the third direction,
the first gap being divided by a reference plane relative to the third direction;
the first MD structures and the first metallization layer are over the reference plane;
the cell region further comprises as follows,
second MD structures extending in the second direction, aligning to the beta tracks and being under the reference plane, and
in a first metallization (BM_1st layer) under the reference plane, segments extending in the first direction and aligning to the alpha tracks; and
at one or more of the first or second locations, a corresponding region of the second AR is configurable as a source region or a drain region;
at one or more of the third locations, a corresponding region of the second AR is configurable as a source region; and
at one or more of the fourth locations, a corresponding region of the second AR is free from being configurable as a source region or a drain region.

3. The cell region of claim 2, wherein:
in the first metallization layer (M_1st layer),
relative to the second direction,
each of the segments has substantially a same width;
in the M_1st layer, a first one of the segments aligns with the first alpha track and is a first power grid (PG) segment (first M_1st_PG segment),
the first M_1st_PG segment being configured for a first reference voltage; and
the first M_1st_PG segment is a rail that extends continuously (i) between the left and right boundaries of the cell region and (ii) beyond each of the left and right boundaries of the cell region.

4. The cell region of claim 3, wherein:
in the BM_1st layer,
relative to the second direction,
each of the segments has substantially a same width;
in the BM_1st layer, a first one of the segments aligns with the first alpha track and is a first PG segment (first BM_1st_PG segment),
the first BM_1st_PG segment being configured for a second reference voltage different than the first reference voltage; and
the first BM_1st_PG segment is a rail that extends continuously (i) between the left and right boundaries of the cell region and (ii) beyond each of the left and right boundaries of the cell region.

5. The cell region of claim 2, wherein:
in the first metallization layer (M_1st layer), a first one of the segments is a first power grid (PG) segment (first M_1st_PG segment),
the first M_1st_PG segment being configured for a first reference voltage;
in the BM_1st layer, a first one of the segments is a first PG segment (first BM_1st_PG segment),
the first BM_1st_PG segment being configured for a second reference voltage different than the first reference voltage;
in a second metallization (M_2nd layer) over the M_1st layer,
the cell region further comprises segments (M_2nd segments) extending in the second direction;
a first one of the M_2nd segments is a first PG segment (first M_2nd_PG segment) that is configured for the first reference voltage;
the first M_2nd_PG segment is coupled to the first M_1st_PG segment;
in a second metallization (BM_2nd layer) under the BM_1st layer,
the cell region further comprises segments (BM_2nd segments) extending in the second direction;
a first one of the BM_2nd segments is a first PG segment (first BM_2nd_PG segment) that is configured for the second reference voltage;
the first BM_2nd_PG segment is coupled to the first BM_1st_PG segment; and
relative to the first direction,
the first M_2nd_PG segment and the first BM_2nd_PG segment overlap a same one of the beta tracks.

6. The cell region of claim 5, wherein:
regarding the beta track which is overlapped by each of the first M_2nd_PG segment and the first BM_2nd_PG segment, and
relative to the first direction,
the beta track intersects a central area of the cell region.

7. The cell region of claim 5, wherein:
regarding the beta track is overlapped by each of the first M_2nd_PG segment and the first BM_2nd_PG segment, and
relative to the first direction,
the beta track is proximal to the left boundary or the right boundary of the cell region such that each of the first M_2nd_PG segment and the first BM_2nd_PG segment overlaps the left boundary or the right boundary of the cell region.

8. The cell region of claim 2, wherein:
in the first metallization layer (M_1st layer), a first one of the segments is a first power grid (PG) segment (first M_1st_PG segment),
the first M_1st_PG segment being configured for a first reference voltage;
in the BM_1st layer, a first one of the segments is a first PG segment (first BM_1st_PG segment),
the first BM_1st_PG segment being configured for a second reference voltage different than the first reference voltage;
in a second metallization (M_2nd layer) over the M_1st layer,
the cell region further comprises segments (M_2nd segments) extending in the second direction;
a first one of the M_2nd segments is a first PG segment (first M_2nd_PG segment) that is configured for the first reference voltage;
the first M_2nd_PG segment is coupled to the first M_1st_PG segment;
in a second metallization (BM_2nd layer) under the BM_1st layer,
the cell region further comprises segments (BM_2nd segments) extending in the second direction;
a first one of the BM_2nd segments is a first PG segment (first BM_2nd_PG segment) that is configured for the second reference voltage;
the first BM_2nd_PG segment is coupled to the first BM_1st_PG segment;
relative to the first direction,
the first M_2nd_PG segment and the first BM_2nd_PG segment overlap different ones of the beta tracks.

9. The cell region of claim 8, wherein:
regarding the different beta tracks which are correspondingly overlapped by the first M_2nd_PG segment and the first BM_2nd_PG segment, and
relative to the first direction,
the beta track which is overlapped by the first M_2nd_PG segment is also proximal to the left boundary or the right boundary of the cell region and the beta track which is overlapped by the first BM_2nd_PG segment is also proximal correspondingly to the right boundary or left boundary of the cell region such that the first M_2nd_PG segment overlaps the left boundary or the right boundary of the cell region and the first BM_2nd_PG segment correspondingly overlaps the right boundary or left boundary of the cell region.

10. The cell region of claim 8, wherein:
regarding the different beta tracks which are correspondingly overlapped by the first M_2nd_PG segment and the first BM_2nd_PG segment, and
relative to the first direction,
the first M_2nd_PG segment and the first BM_2nd_PG segment are spaced apart from each other correspondingly towards the left and right boundaries or the right and left boundaries such that a central area of the cell region is free from being overlapped by each of the first M_2nd_PG segment and the first BM_2nd_PG segment.

11. The cell region of claim 1, wherein:
the first locations are at intersections of (A) second through antepenultimate ones of the alpha tracks and (B) alternating second through preantepenultimate ones of the beta tracks, and
the second locations are at intersections of (A) the second through penultimate alpha tracks and (B) a penultimate one of the beta tracks;
the third locations are at intersections of (E) first and last ones of the alpha tracks and (F) the alternating second through preantepenultimate beta tracks, and
the fourth locations are at intersections of (A) the first and last alpha tracks and (B) the penultimate beta track.

12. A device comprising first and second cell regions each of which includes:
a first active region (AR) extending in a first direction;
first metal-to-source/drain contact (MD) structures extending in a second direction perpendicular to the first direction and aligning to beta tracks;
in a first metallization layer, segments therein (M_1st segments) extending in the first direction and aligning to alpha tracks; and
for one or more first or second locations, a corresponding region of the first AR being configurable as a source region or a drain region;
for one or more third locations, a corresponding region of the first AR being configurable as a source region,
regions of the first AR at the third locations being free of being configurable as a drain region;
for one or more fourth location, a corresponding region of the AR being free from being configurable as a source region or a drain region;
each of the first to fourth locations being at an intersection of (A) a corresponding one of the alpha tracks and (B) a corresponding one of the beta tracks;
first and last ones of the beta tracks substantially aligning correspondingly to left and right boundaries of the cell region;
the first and last alpha tracks substantially aligning correspondingly to top and bottom boundaries of the cell region;
relative to the second direction, the first cell region being stacked on the second cell region;
for each of the first and second cell regions,
one or more ones of the M_1st segments aligned to the first alpha track are also overlapping the top boundary, and
the last alpha track of the first cell region is substantially collinear with the first alpha track of the second cell region such that the one or more ones of the M_1st segments aligned to the first alpha track of the second cell region are shared by the first cell region.

13. The device of claim 12, wherein:
for each of the first and second cell regions, the first AR has a first type of conductivity;
each of the first and second cell regions further comprises a second AR extending in the first direction and having a second type of conductivity different than the first type of conductivity;
each of the first and second cell regions has a complimentary field-effect transistor (CFET) architecture including as follows,
the first AR being aligned with the second AR relative to the first and second directions, and
the first AR being stacked over the second AR relative to a third direction perpendicular to each of the first and second directions;
the first and second ARs being separated by a first gap relative to the third direction,
the first gap being divided by a reference plane relative to the third direction;
the first MD structures and the first metallization layer are over the reference plane;
each of the first and second cell regions further comprises as follows,
second MD structures extending in the second direction, aligning to the beta tracks and being under the reference plane, and
in a first metallization (BM_1st layer) under the reference plane, segments (BM_1st segments) extending in the first direction and aligning to the alpha tracks; and
for each of the first and second cell regions,
at one or more of the first or second locations, a corresponding region of the second AR is configurable as a source region or a drain region,
at one or more of the third locations, a corresponding region of the second AR is configurable as a source region, and
at one or more of the fourth locations, a corresponding region of the second AR is free from being configurable as a source region or a drain region;
for each of the first and second cell regions,
one or more ones of the BM_1st segments aligned to the first alpha track are also overlapping the top boundary, and
one or more ones of the BM_1st segments aligned to the first alpha track of the second cell region are shared by the first cell region.

14. A method of forming a cell region of a device, the method comprising:
forming a first active region (AR) that extend in a first direction;
forming first metal-to-source/drain contact (MD) structures that extend in a second direction perpendicular to the first direction and align to beta tracks;
forming segments (M_1st segments) in a first metallization layer (M_1st layer) that extend in the first direction and align to alpha tracks; and
the forming a first active region (AR) including as follows,
for one or more first or second locations, doping a corresponding region of the first AR as a source region or a drain region;
for one or more third locations, doping a corresponding region of the first AR as a source region,
regions of the first AR at the third locations being free of being configurable as a drain region;
for one or more fourth locations, avoiding a corresponding region of the AR being doped as a source region or a drain region;
each of the first to fourth locations being at an intersection of (A) a corresponding one of the alpha tracks and (B) a corresponding one of the beta tracks;
first and last ones of the beta tracks substantially aligning correspondingly to left and right boundaries of the cell region; and
the first and last alpha tracks substantially aligning correspondingly to top and bottom boundaries of the cell region.

15. The method of claim 14, wherein:
the forming a first active region (AR) further includes doping the first AR to have a first type of conductivity,
the method further comprises forming a second AR that extends in the first direction;
the forming a second AR includes doping the second AR to have a second type of conductivity different than the first type of conductivity;
the method further comprises arranging the cell region to have a complimentary field-effect transistor (CFET) architecture including as follows,
aligning the first AR with the second AR relative to the first and second directions, and
stacking the first AR over the second AR relative to a third direction perpendicular to each of the first and second directions, resulting in the first and second ARs being separated by a first gap relative to the third direction,
the first gap being divided by a reference plane relative to the third direction, and
the first MD structures and the first metallization layer being over the reference plane;
under the reference plane, forming second MD structures that extend in the second direction and align to the beta tracks, and
forming segments (BM_1st segments) in a first metallization (BM_1st layer) under the reference plane that extend in the first direction and align to the alpha tracks; and
the forming a second AR includes as follows,
for one or more of the first or second locations, doping a corresponding region of the second AR as a source region or a drain region,
for one or more of the third locations, doping a corresponding region of the second AR as a source region; and
for one or more of the fourth locations, avoiding a corresponding region of the second AR being doped as a source region or a drain region.

16. The method of claim 15, wherein:
a first one of the M_1st segments is a first power grid (PG) segment (first M_1st_PG segment),
the first M_1st_PG segment being configured for a first reference voltage;
a first one of the BM_1st segments is a first PG segment (first BM_1st_PG segment),
the first BM_1st_PG segment being configured for a second reference voltage different than the first reference voltage;
the method further comprises:
forming segments (M_2nd segments) in a second metallization (M_2nd layer) over the M_1st layer that extend in the second direction,
a first one of the M_2nd segments being a first PG segment (first M_2nd_PG segment) that is configured for the first reference voltage; and
coupling the first M_2nd_PG segment to the first M_1st_PG segment; and
the arranging the cell region to have a complimentary field-effect transistor (CFET) architecture further including as follows,
forming segments (BM_2nd segments) in a second metallization (BM_2nd layer) under the BM_1st layer that extend in the second direction,
a first one of the BM_2nd segments being a first PG segment (first BM_2nd_PG segment) that is configured for the second reference voltage;
coupling the first BM_2nd_PG segment to the first BM_1st_PG segment; and
relative to the first direction,
locating the first M_2nd_PG segment and the first BM_2nd_PG segment overlap a same one of the beta tracks.

17. The method of claim 16, wherein the arranging the cell region to have a complimentary field-effect transistor (CFET) architecture further includes:
regarding the beta track which is overlapped by each of the first M_2nd_PG segment and the first BM_2nd_PG segment, and
relative to the first direction,
locating the beta track to intersect a central area of the cell region.

18. The method of claim 16, wherein the arranging the cell region to have a complimentary field-effect transistor (CFET) architecture further includes:
regarding the beta track is overlapped by each of the first M_2nd_PG segment and the first BM_2nd_PG segment, and
relative to the first direction,
locating the beta track to be proximal to the left boundary or the right boundary of the cell region such that each of the first M_2nd_PG segment and the first BM_2nd_PG segment overlaps the left boundary or the right boundary of the cell region.

19. The method of claim 15, wherein:
a first one of the M_1st segments is a first power grid (PG) segment (first M_1st_PG segment),
the first M_1st_PG segment being configured for a first reference voltage;
a first one of the BM_1st segments is a first PG segment (first BM_1st_PG segment),
the first BM_1st_PG segment being configured for a second reference voltage different than the first reference voltage;
the method further comprises:
forming segments (M_2nd segments) in a second metallization (M_2nd layer) over the M_1st layer that extend in the second direction,
a first one of the M_2nd segments being a first PG segment (first M_2nd_PG segment) that is configured for the first reference voltage; and
coupling the first M_2nd_PG segment to the first M_1st_PG segment; and
the arranging the cell region to have a complimentary field-effect transistor (CFET) architecture further including as follows,
forming segments (BM_2nd segments) in a second metallization (BM_2nd layer) under the BM_1st layer that extend in the second direction,
a first one of the BM_2nd segments being a first PG segment (first BM_2nd_PG segment) that is configured for the second reference voltage;
coupling the first BM_2nd_PG segment to the first BM_1st_PG segment; and
relative to the first direction,
locating the first M_2nd_PG segment and the first BM_2nd_PG segment differently so that the first M_2nd_PG segment and the first BM_2nd_PG segment overlap different ones of the beta tracks.

20. The method of claim 14, wherein:
the first locations are at intersections of (A) second through antepenultimate ones of the alpha tracks and (B) alternating second through preantepenultimate ones of the beta tracks, and
the second locations are at intersections of (A) the second through penultimate alpha tracks and (B) a penultimate one of the beta tracks;
the third locations are at intersections of (E) first and last ones of the alpha tracks and (F) the alternating second through preantepenultimate beta tracks; and
the fourth locations being at intersections of (A) the first and last alpha tracks and (B) the penultimate beta track.
